(19) United States
(12) Patent Application Publication
(10) Pub. No.: US 2024/0194752 A1
(43) Pub. Date: Jun. 13, 2024

(54) SEMICONDUCTOR DEVICE

(71) Applicant: SAMSUNG ELECTRONICS CO., LTD., SUWON-SI (KR)

(72) Inventors: Woo Kyung YOU, Suwon-si (KR); Sang Koo KANG, Suwon-si (KR); Jun Chae LEE, Suwon-si (KR); Koung Min RYU, Suwon-si (KR); Woo Jin LEE, Suwon-si (KR)

(21) Appl. No.: 18/502,352

(22) Filed: Nov. 6, 2023

(30) Foreign Application Priority Data
Dec. 13, 2022 (KR) 10-2022-0173450

(51) Int. Cl. H01L 29/417; H01L 29/06; H01L 29/40; H01L 29/423; H01L 29/775; H01L 29/78

(52) U.S. Cl. CPC H01L 29/41791; H01L 29/0673; H01L 29/401; H01L 29/41733; H01L 29/42392; H01L 29/775; H01L 29/7851

(57) ABSTRACT

A semiconductor device includes a substrate, an active pattern disposed on the substrate and extending in a first direction, gate electrodes covering the active pattern and extending in a second direction, a gate spacer disposed on a sidewall of each of the gate electrodes, a source/drain pattern disposed between adjacent ones of the gate electrodes, an etch stop film disposed along a sidewall of the gate spacer and a profile of the source/drain pattern, an interlayer insulating film disposed between the adjacent ones of the gate electrodes with a contact trench exposing the source/drain pattern defined therein, a liner film disposed on an outer sidewall of the contact trench, and a source/drain contact disposed on the liner film and filling the contact trench, in which the source/drain contact is connected to the source/drain pattern. At least a portion of the liner film may be disposed in the source/drain pattern.

### CROSS-REFERENCE TO RELATED APPLICATION

This application claims priority under 35 U.S.C. § 119 to Korean Patent Application No. 10-2022-0173450, filed on Dec. 13, 2022, in the Korean Intellectual Property Office, the contents of which are herein incorporated by reference in their entirety.

### TECHNICAL FIELD

The present disclosure relates to a semiconductor device.

### DISCUSSION OF RELATED ART

Multi-gate transistor is one of the scaling schemes proposed for increasing an integration density of a semiconductor device. In the multi-gate transistor, a multi-channel active pattern (or a silicon body) in a shape of a fin or a nanowire is formed on a substrate, and a gate is formed on a surface of the multi-channel active pattern.

Because such a multi-gate transistor uses a three-dimensional channel, it is easy to scale. Further, current control capability of the multi-gate transistor may be enhanced without increasing a gate length of the multi-gate transistor. In addition, the multi-gate transistor may effectively suppress short channel effect (SCE) by controlling the effective channel length. For example, by increasing the effective number of gates, the electrostatic control of the channel by the gate may be enhanced, and thus, short-channel effects may be reduced.

As a pitch size of the semiconductor device decreases, research is needed to reduce capacitance between contacts and to secure electrical stability in the semiconductor device. Also, robust processes may be required to fabricate the contact structures for the multi-gat transistor, so that the reliability of the semiconductor device may be secured.

### SUMMARY

Embodiments of the present disclosure provide a semiconductor device with enhanced performance and reliability.

According to an embodiment of the present disclosure, there is provided a semiconductor device including, a substrate, an active pattern disposed on the substrate and extending in a first direction, a plurality of gate electrodes covering the active pattern and extending in a second direction, the second direction intersecting the first direction, a gate spacer disposed on a sidewall of each of the plurality of gate electrodes, a source/drain pattern disposed between adjacent ones of the plurality of gate electrodes, an etch stop film disposed along a sidewall of the gate spacer and a profile of the source/drain pattern, an interlayer insulating film disposed between the adjacent ones of the plurality of gate electrodes, in which a contact trench exposing the source/drain pattern is defined in the interlayer insulating film, a liner film disposed on an outer sidewall of the contact trench, and a source/drain contact disposed on the liner film and filling the contact trench, in which the source/drain contact is connected to the source/drain pattern. At least a portion of the liner film may be disposed in the source/drain pattern.

According to an embodiment of the present disclosure, there is provided a semiconductor device including, a substrate, an active pattern disposed on the substrate and extending in a first direction, a plurality of gate electrodes covering the active pattern and extending in a second direction, the second direction intersecting the first direction, a plurality of gate spacers, each being disposed on a sidewall of each of the plurality of gate electrodes, a first gate capping film disposed on the each of the plurality of gate electrodes and the each of the plurality of gate spacers, a source/drain pattern disposed between adjacent ones of the plurality of gate electrodes, an etch stop film disposed along a sidewall of the each of the plurality of gate spacers and a profile of the source/drain pattern, a liner film extending along a profile of the etch stop film, a sidewall of the first gate capping film, and an upper surface of the first gate capping film, in which at least a portion of the liner film is disposed in the source/drain pattern, a second gate capping film disposed on the liner film and overlapping the first gate capping film in a third direction, the third direction intersecting the first direction and the second direction, and a source/drain contact disposed between the adjacent ones of the plurality of gate electrodes and connected to the source/drain pattern. The liner film may include an oxide-based insulating material.

According to an embodiment of the present disclosure, there is provided a semiconductor device including, a substrate, an active pattern disposed on the substrate, in which the active pattern includes a lower pattern extending in a first direction, and at least one sheet pattern spaced apart from the lower pattern in a third direction, the third direction intersecting the first direction, a field insulating film covering a sidewall of the lower pattern, a plurality of gate electrodes disposed on the lower pattern and covering the at least one sheet pattern, in which each of the plurality of gate electrodes extends in a second direction, the second direction intersecting the first direction and the third direction, a plurality of gate spacers, each being disposed on a sidewall of the each of the plurality of gate electrodes, a plurality of gate capping films respectively disposed on the plurality of gate electrodes, a source/drain pattern disposed between adjacent ones of the plurality of gate electrodes, and connected to the at least one sheet pattern, an etch stop film disposed along an upper surface of the field insulating film, a sidewall of the each of the plurality of gate spacers, and a profile of the source/drain pattern, an interlayer insulating film disposed between the adjacent ones of the plurality of gate electrodes, in which a contact trench exposing the source/drain pattern is defined in the interlayer insulating film, a liner film disposed on an outer sidewall of the contact trench, and a source/drain contact disposed on the liner film and filling the contact trench, in which the source/drain contact is connected to the source/drain pattern. A vertical level of a bottom surface of the source/drain contact based on an upper surface of the substrate may be lower than a vertical level of a bottom surface of the liner film based on the upper surface of the substrate. The etch stop film may include a nitride-based insulating material. The liner film may include an oxide-based insulating material At least a portion of the liner film may be in contact with the source/drain pattern.

### BRIEF DESCRIPTION OF THE DRAWINGS

The above and other aspects and features of the present disclosure will become more apparent by describing in detail illustrative embodiments thereof with reference to the accompanying drawings, in which:

FIG. 1 is an illustrative layout diagram for illustrating a semiconductor device according to an embodiment of the present disclosure;

FIG. 2 is an illustrative cross-sectional view taken along line A-A in FIG. 1;

FIG. 3 is an illustrative cross-sectional view taken along line B-B in FIG. 1;

FIG. 4 is an illustrative cross-sectional view taken along line C-C in FIG. 1;

FIG. 5 to FIG. 8 are diagrams each for illustrating a semiconductor device according to an embodiment of the present disclosure;

FIG. 9 and FIG. 10 are diagrams for illustrating a semiconductor device according to an embodiment of the present disclosure;

FIG. 11 and FIG. 12 are diagrams for illustrating a semiconductor device according to an embodiment of the present disclosure;

FIG. 13 to FIG. 17 are diagrams for illustrating a semiconductor device according to an embodiment of the present disclosure; and

FIG. 18 to FIG. 27 are diagrams of intermediate structures corresponding to intermediate steps for illustrating a method for manufacturing a semiconductor device according to an embodiment of the present disclosure.

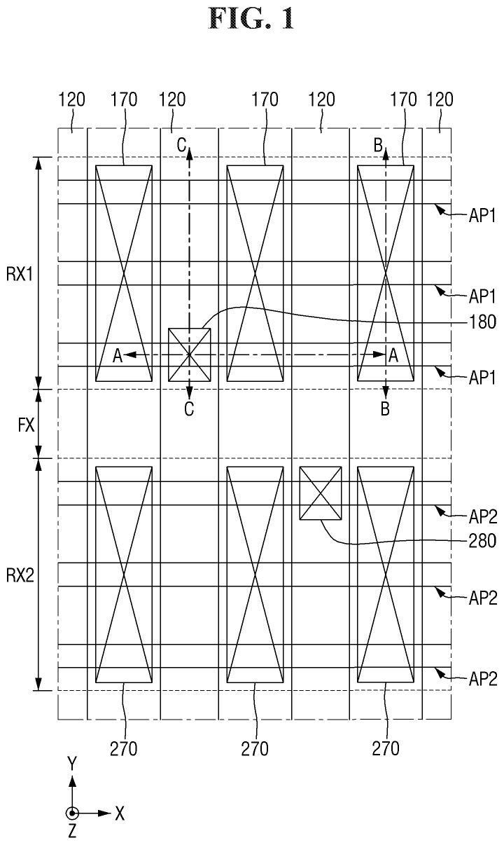

Since the drawings in FIGS. 1-27 are intended for illustrative purposes, the elements in the drawings are not necessarily drawn to scale. For example, some of the elements may be enlarged or exaggerated for clarity purpose.

### DETAILED DESCRIPTIONS OF THE EMBODIMENTS

It will be understood that, although the terms “first”, “second”, “upper portion”, “lower portion”, etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure. Also, a lower element or an upper component could be termed an upper element or a lower component without departing from the technical spirits of the present disclosure.

In a diagram of a semiconductor device according to an embodiment of the present disclosure, a fin-type field-effect transistor (FinFET) including a fin-type pattern-shaped channel area, a transistor including nanowires or nanosheets, MBCFET™ (Multi-Bridge Channel Field Effect Transistor) or a vertical field-effect transistor (Vertical FET) is shown illustratively. However, the present disclosure is not limited thereto. For example, a semiconductor device according to an embodiment of the present disclosure may include a tunneling field-effect transistor (tunneling FET) or a three-dimensional (3D) transistor. For example, the three-dimensional (3D) transistor may be a multi-gate transistor uses a three-dimensional (3D) channel such as, for example, a gate-all-around field-effect transistor (GAAFET). For example, a semiconductor device according to an embodiment of the present disclosure may include a planar transistor. In addition, the present disclosure may be applied to a 2D (two-dimensional) material field-effect transistor (2D material based FETs) and a heterostructure thereof.

A semiconductor device according to an embodiment of the present disclosure may include a bipolar junction transistor (BJT), a lateral double diffusion transistor (LDMOS), or the like.

Hereinafter, embodiments of the present disclosure will be described with reference to the accompanying drawings.

First, referring to FIG. 1 to FIG. 4, a semiconductor device according to an embodiment of the present disclosure is described.

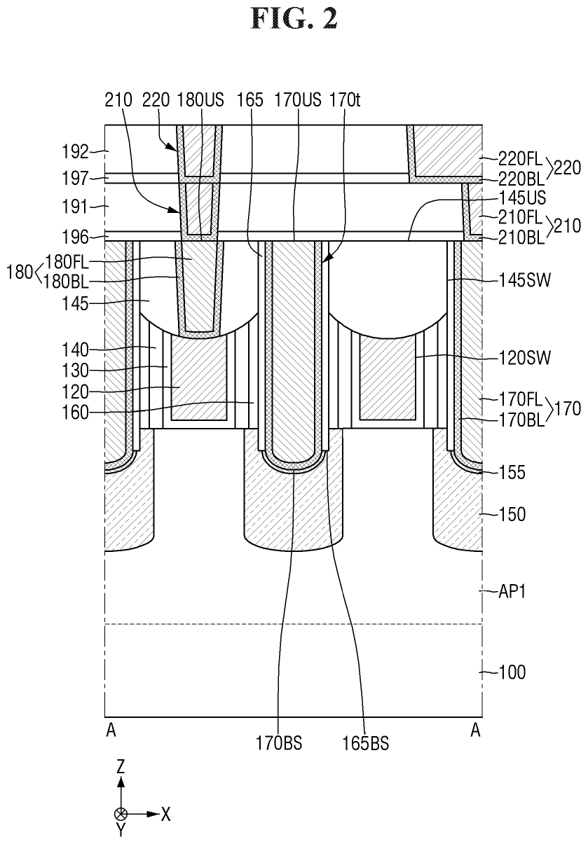

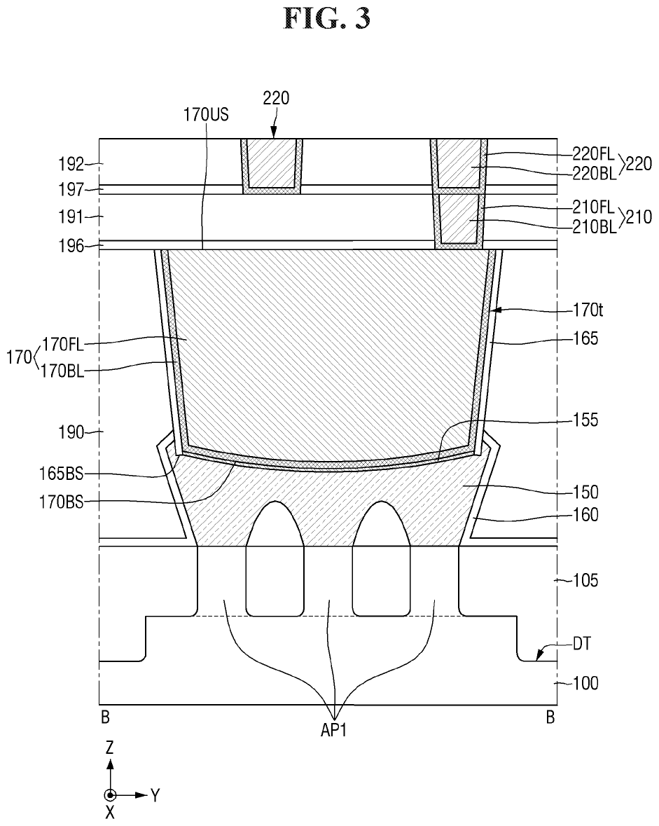

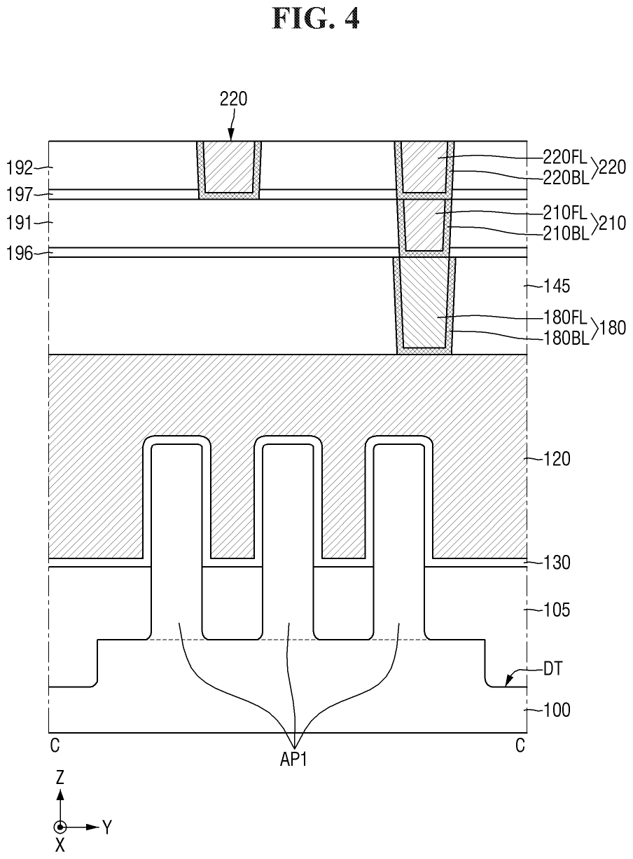

FIG. 1 is an illustrative layout diagram for illustrating a semiconductor device according to an embodiment of the present disclosure. FIG. 2 is an illustrative cross-sectional view taken along line A-A in FIG. 1. FIG. 3 is an illustrative cross-sectional view taken along line B-B in FIG. 1. FIG. 4 is an illustrative cross-sectional view taken along line C-C in FIG. 1.

In FIG. 2, it is illustrated that the via plug 210 connected to a first source/drain contact 170 and the via plug 210 connected to a gate contact 180 are adjacent to each other in the first direction X while being disposed on one first active pattern AP1. However, the arrangement of the via plugs 210 is intended only for convenience of illustration, and the present disclosure is not limited thereto.

Similar to the cross-sectional view taken in the first direction X and along the first active pattern AP1, a cross-sectional view taken in the first direction X and along a second active pattern AP2 may be similar to FIG. 2 except for positions of the via plug 210 and the wiring line 220.

Referring to FIG. 1 to FIG. 4, the semiconductor device according to an embodiment of the present disclosure may include a substrate 100, at least one first active pattern AP1, at least one second active pattern AP2, a plurality of gate electrodes 120, the first source/drain contact 170, a second source/drain contact 270, and gate contacts 180 and 280.

The substrate 100 may include a first active area RX1, a second active area RX2, and a field area FX. The field area FX may be formed to be immediately adjacent to the first active area RX1 and the second active area RX2. For example, the field area FX may be interposed between the first active area RX1 and the second active area RX2. A boundary may be defined between the field area FX and each of the first active area RX1 and the second active area RX2.

The first active area RX1 and the second active area RX2 are spaced apart from each other in a second direction Y. The first active area RX1 and the second active area RX2 may be isolated from each other via the field area FX.

An element isolation layer may be disposed around each of the first active area RX1 and the second active area RX2 that are spaced apart from each other. In this regard, a portion of the element isolation layer disposed between the first active area RX1 and the second active area RX2 may be the field area FX. For example, an area where a channel area of a transistor is formed may be an active area. An area defining the channel area of the transistor formed in the active area may be a field area. Alternatively, the active area may be an area in which a fin-shaped pattern or a nanosheet used as the channel area of the transistor is formed, and the field area may be an area in which the fin-shaped pattern or the nanosheet used as the channel area is not formed.

As shown in FIGS. 3 and 4, the field area FX may be defined by a deep trench DT. However, the present disclosure is not limited thereto.

In one example, one of the first active area RX1 and the second active area RX2 may be an area in which a PMOS is formed, and the other thereof may be an area in which an NMOS is formed. In another example, each of the first active area RX1 and the second active area RX2 may be an area in which a PMOS is formed. In still another example, each of the first active area RX1 and the second active area RX2 may be an area in which an NMOS is formed.

The substrate 100 may be a silicon (Si) substrate or a silicon-on-insulator (SOI) substrate. Alternatively, the substrate 100 may include, for example, silicon germanium (SiGe), silicon germanium on insulator (SGOI), indium antimonide (InSb), a lead telluride (PbTe) compound, indium arsenide (InAs), indium phosphide (InP), gallium phosphide (GaP), gallium arsenide (GaAs), gallium antimonide (GaSb), or indium gallium arsenide (InGaAs). However, the present disclosure is not limited thereto. Alternatively, the substrate 100 may be composed of a base substrate and an epitaxial layer formed on the base substrate. The substrate 100 may include a conductive area, for example, a well doped with impurities or a structure doped with impurities. In addition, the substrate 100 may include one or more semiconductor layers or structures and may include active or operable portions of semiconductor devices.

At least one first active pattern AP1 may be formed in the first active area RX1. The first active pattern AP1 may protrude from a portion of the substrate 100 in the first active area RX1. The first active pattern AP1 may extend long along the first direction X while being disposed on the substrate 100. For example, the first active pattern AP1 may include a long side extending in the first direction X and a short side extending in the second direction Y. In this regard, the first direction X may intersect each of the second direction Y and the third direction Z. Further, the second direction Y may intersect the third direction Z. The third direction Z may be a thickness direction of the substrate 100.

At least one second active pattern AP2 may be formed in the second active area RX2. A description about the second active pattern AP2 may be substantially the same as the description about the first active pattern AP1. Each of the first active pattern AP1 and the second active pattern AP2 may extend in the first direction X parallel to the top surface of the substrate 100.

Each of the first active pattern AP1 and the second active pattern AP2 may be a multi-channel active pattern. In the semiconductor device according to an embodiment of the present disclosure, each of the first active pattern AP1 and the second active pattern AP2 may be, for example, a fin-shaped pattern. Each of the first active pattern AP1 and the second active pattern AP2 may be used as a channel area of a transistor. It is illustrated that each of the number of the first active patterns AP1 and the number of the second active patterns AP2 is three. However, the present disclosure is not limited thereto. Each of the number of the first active patterns AP1 and the number of the second active patterns AP2 may be at least one. In an embodiment of the present disclosure, each of the number of the first active patterns AP1 and the number of the second active patterns AP2 may be one, two or more than three.

Each of the first active pattern AP1 and the second active pattern AP2 may be a portion of the substrate 100 or may include an epitaxial layer grown from the substrate 100. Each of the first active pattern AP1 and the second active pattern AP2 may include, for example, an elemental semiconductor material such as silicon (Si) or germanium (Ge). Alternatively, each of the first active pattern AP1 and the second active pattern AP2 may include a compound semiconductor. For example, each of the first active pattern AP1 and the second active pattern AP2 may include a group IV-IV compound semiconductor or a group III-V compound semiconductor.

The group IV-IV compound semiconductor may include, for example, a binary compound including two of carbon (C), silicon (Si), germanium (Ge), and tin (Sn), a ternary compound including three thereof, or a compound obtained by doping a group IV element thereto. In an embodiment of the present disclosure, each of the first active pattern AP1 and the second active pattern AP2 may include, for example, silicon carbide (SiC), silicon germanium (SiGe), or silicon germanium carbide (SiGeC).

The group III-V compound semiconductor may include, for example, a binary compound obtained by combining one of aluminum (Al), gallium (Ga), and indium (In) as a group III element and one of phosphorus (P), arsenic (As), and antimony (Sb) as a group V element with each other, a ternary compound obtained by combining two of aluminum (Al), gallium (Ga), and indium (In) as a group III element and one of phosphorus (P), arsenic (As), and antimony (Sb) as a group V with each other, or a quaternary compound obtained by combining three of aluminum (Al), gallium (Ga), and indium (In) as a group III element and one of phosphorus (P), arsenic (As), and antimony (Sb) as a group V with each other. In an embodiment of the present disclosure, each of the first active pattern AP1 and the second active pattern AP2 may include, for example, gallium arsenide (GaAs), gallium antimonide (GaSb), gallium phosphide (GaP), indium arsenide (InAs), indium phosphide (InP), indium antimonide (InSb), or indium gallium arsenide (InGaAs), or the like.

In an embodiment of the present disclosure, the first active pattern AP1 and the second active pattern AP2 may include the same material. For example, each of the first active pattern AP1 and the second active pattern AP2 may be a fin-shaped pattern including silicon (Si). Alternatively, for example, each of the first active pattern AP1 and the second active pattern AP2 may be a fin-shaped pattern including silicon germanium (SiGe). In another example, the first active pattern AP1 and the second active pattern AP2 may include different materials. For example, the first active pattern AP1 may be a fin-shaped pattern including silicon (Si), and the second active pattern AP2 may be a fin-shaped pattern including silicon germanium (SiGe).

A field insulating film 105 may be formed on the substrate 100. The field insulating film 105 may be disposed continuously along the first active area RX1, the second active area RX2, and the field area FX. The field insulating film 105 may fill the deep trench DT.

The field insulating film 105 may cover a sidewall of the first active pattern AP1 and a sidewall of the second active pattern AP2. The first active pattern AP1 and the second active pattern AP2 may be defined on the substrate 100 by the field insulating film 105 filling the deep trench DT. For example, the first active pattern AP1 and the second active pattern AP2 may correspond to portions of the substrate 100 that are surrounded by the field insulating film 105. Each of the first active pattern AP1 and the second active pattern AP2 may protrude upwardly beyond an upper surface of the field insulating film 105. The field insulating film 105 may include, for example, an oxide film, a nitride film, an oxynitride film, or a combination film thereof.

The plurality of gate electrodes 120 may be disposed on the substrate 100. For example, the plurality of gate electrodes 120 may be disposed on the field insulating film 105. Each of the plurality of gate electrodes 120 may extend in the second direction Y parallel to a top surface of the substrate 100 and intersecting the first direction X. The plurality of gate electrodes 120 may be spaced apart from each other in the first direction X and may extend in a parallel manner to each other.

The plurality of gate electrodes 120 may be disposed on the first active pattern AP1 and the second active pattern AP2. The plurality of gate electrodes 120 may cover the first active pattern AP1 and the second active pattern AP2. Each of the plurality of gate electrodes 120 may intersect the first active pattern AP1 and the second active pattern AP2.

It is illustrated that each of the plurality of gate electrodes 120 is disposed continuously along the first active area RX1 and the second active area RX2. However, the present disclosure is not limited thereto. For example, each of some of the plurality of gate electrodes 120 may be divided into two portions via a gate isolation structure disposed on the field insulating film 105 such that the two portions may be respectively disposed on the first active area RX1 and the second active area RX2.

Each of the plurality of gate electrodes 120 may intersect the first active pattern AP1 and the second active pattern AP2. Each of the plurality of gate electrodes 120 may surround a portion of each of the first active pattern AP1 and the second active pattern AP2 protruding upwardly beyond the upper surface of the field insulating film 105. Each of the plurality of gate electrodes 120 may include a long side extending in the second direction Y and a short side extending in the first direction X.

An upper surface of each of the plurality of gate electrodes 120 may be a concave curved surface recessed toward an upper surface of the first active pattern AP1. However, the present disclosure is not limited thereto. For example, unlike what is illustrated, the upper surface of each of the plurality of gate electrodes 120 may be a flat plane.

Each of the plurality of gate electrodes 120 may include at least one of, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TIC), tantalum carbonitride (TaCN), tungsten (W), aluminum (Al), copper (Cu), cobalt (Co), titanium (Ti), tantalum (Ta), nickel (Ni), platinum (Pt), nickel platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), manganese (Mn), zirconium (Zr), or combinations thereof. However, the present disclosure is not limited thereto.

Each of the plurality of gate electrodes 120 may include, for example, a conductive metal oxide, a conductive metal oxynitride, or the like. In this regard, the conductive metal oxide, and the conductive metal oxynitride may include oxidized products of the above-mentioned materials. However, the present disclosure is not limited thereto.

It is illustrated that each of the plurality of gate electrodes 120 is embodied as a single film. However, this is only an example, and each of the plurality of gate electrodes 120 may be formed by stacking a plurality of conductive layers. For example, each of the plurality of gate electrodes 120 may include a work-function control film that controls a work-function and a filling conductive film that fills a space defined by the work-function control film. The work-function control film may include, for example, at least one of titanium nitride (TiN), tantalum nitride (TaN), titanium carbide (TiC), tantalum carbide (TaC), titanium silicon nitride (TiSiN), tantalum silicon nitride (TaSiN), tantalum titanium nitride (TaTiN), titanium aluminum nitride (TiAIN), tantalum aluminum nitride (TaAIN), tungsten nitride (WN), titanium aluminum carbonitride (TiAlCN), tantalum carbonitride (TaCN), niobium nitride (NbN), niobium carbide (NbC), molybdenum nitride (MoN), molybdenum carbide (MoC), tungsten carbide (WC), titanium aluminum carbide (TiAlC), or combinations thereof. The filling conductive film may include, for example, tungsten (W) or aluminum (Al).

Each of the plurality of gate electrodes 120 may be disposed on each of both opposing sides of a source/drain pattern 150 to be described later.

In one example, each of the gate electrodes 120 disposed on each of both opposing sides of the source/drain pattern 150 may act as a normal gate electrode used as a gate of a transistor. In another example, the gate electrode 120 disposed on one side of the source/drain pattern 150 may be used as a gate of a transistor, while the gate electrode 120 disposed on the other side of the source/drain pattern 150 may act as a dummy gate electrode.

Each of a plurality of gate spacers 140 may be disposed on a sidewall 120SW of each of the plurality of gate electrodes 120. That is, one of the plurality of gate spacers may be disposed on a sidewall 120SW of a corresponding one of the plurality of gate electrodes. Each of the plurality of gate spacers 140 does not contact each of the plurality of gate electrodes 120. A gate insulating film 130 may be disposed between the gate spacer 140 and the sidewall 120SW of the gate electrode 120. Each of the plurality of gate spacers 140 may extend along the sidewall 120SW of each of the plurality of gate electrodes 120 in the second direction Y. Each of the plurality of gate spacers 140 may include, for example, at least one of silicon nitride (Si₃N₄), silicon oxynitride (SiON), silicon oxide (SiO₂), silicon oxycarbonitride (SiOCN), silicon carbonitride (SiCN), silicon boron nitride (SiBN), silicon oxyboronitride (SiOBN), silicon oxycarbide (SiOC), or combinations thereof. In an embodiment of the present disclosure, the gate spacer 140 may have a multi-layered structure, which includes at least two different materials selected from, for example, silicon nitride (Si₃N₄), silicon oxynitride (SiON), silicon oxide (SiO₂), silicon oxycarbonitride (SiOCN), silicon carbonitride (SiCN), silicon boron nitride (SiBN), silicon oxyboronitride (SiOBN), or silicon oxycarbide (SiOC).

The gate insulating film 130 may extend along the sidewall 120SW and a bottom surface of each of the plurality of gate electrodes 120. The gate insulating film 130 may be formed on the first active pattern AP1, the second active pattern AP2, and the field insulating film 105. The gate insulating film 130 may be formed between each of the plurality of gate electrodes 120 and each of the plurality of gate spacers 140 corresponding thereto.

The gate insulating film 130 may be formed along a profile of a portion of the first active pattern AP1 protruding upwardly beyond the upper surface of the field insulating film 105 and along the upper surface of the field insulating film 105. Similarly, the gate insulating film 130 may be formed along a profile of a portion of the second active pattern AP2 protruding upwardly beyond the upper surface of the field insulating film 105.

The gate insulating film 130 may include silicon oxide (SiO₂), silicon oxynitride (SiON), silicon nitride (Si₃N₄), or a high dielectric constant (high-k) material having a dielectric constant higher than that of silicon oxide (SiO₂). The high dielectric constant (high-k) material may include at least one of, for example, boron nitride (BN), hafnium oxide (HfO₂), hafnium zirconium oxide (HfZrO₄), hafnium tantalum oxide (Hf₂Ta₂O₉), hafnium silicon oxide (HfSiO₄), hafnium aluminum oxide (HfAlO₃), lanthanum oxide (La₂O₃), lanthanum aluminum oxide (LaAlO₃), zirconium oxide (ZrO₂), zirconium silicon oxide (ZrSiO₄), tantalum oxide (Ta₂O₅), titanium oxide (TiO₂), barium strontium titanium oxide (BaSrTi₂O₆), barium titanium oxide (BaTiO₃), strontium titanium oxide (SrTiO₃), yttrium oxide (Y₂O₃), lithium oxide (Li₂O), aluminum oxide (Al₂O₃), lead scandium tantalum oxide (Pb(Sc,Ta)O₃), or lead zinc niobate [Pb(Zn_{1/3}Nb_{2/3})O₃].

The gate insulating film 130 is illustrated as being embodied as a single film. However, the present disclosure is not limited thereto. For example, the gate insulating film 130 may be embodied as a stack of a plurality of films. The gate insulating film 130 may include an interfacial film disposed between the first active pattern AP1 and the gate electrode 120 and between the second active pattern AP2 and the plurality of gate electrodes 120, and a high dielectric constant insulating film disposed on the interfacial film. For example, the interfacial film may be formed along the profile of the portion of each of the first active pattern AP1 and the second active pattern AP2 protruding upwardly beyond the upper surface of the field insulating film 105.

The semiconductor device according to an embodiment of the present disclosure may include an NC (negative capacitance) FET using a negative capacitor. For example, the gate insulating film 130 may include a ferroelectric material film having ferroelectric properties and a paraelectric material film having paraelectric properties.

The ferroelectric material film may have negative capacitance, and the paraelectric material film may have positive capacitance. For example, when two or more capacitors are connected in series to each other, and capacitance of each of the capacitors has a positive value, a total capacitance is smaller than capacitance of each individual capacitor. On the contrary, when at least one of capacitances of two or more capacitors connected in series to each other has a negative value, a total capacitance may have a positive value, and may be greater than an absolute value of each individual capacitance.

When the ferroelectric material film with negative capacitance and the paraelectric material film with positive capacitance are connected in series to each other, a total capacitance value of the ferroelectric material film and the paraelectric material film connected in series to each other may increase. Using the increase in the total capacitance value, a transistor including the ferroelectric material film may have a subthreshold swing (SS) lower than about 60 mV/decade at room temperature. For example, in a negative capacitance FET (NC-FET), the insulating ferroelectric material layer served as a negative capacitor so that channel surface potential can be amplified more than the gate voltage, and hence the device can operate with SS less than 60 mV/decade at room temperature.

The ferroelectric material film may have ferroelectric properties. The ferroelectric material film may include, for example, at least one of hafnium oxide (HfO₂), hafnium zirconium oxide (HfZrO₄), barium strontium titanium oxide (BaSrTi₂O₆), barium titanium oxide (BaTiO₃), or lead zirconium titanium oxide (Pb(Ti,Zr)O₃). Each of the ferroelectric materials described above, the ratio between metals may vary and the composition may be nonstoichiometric. In this case, in one example, hafnium zirconium oxide (HfZrO₄) may refer to a material obtain by doping hafnium oxide with zirconium (Zr). In another example, hafnium zirconium oxide may refer to a compound of hafnium (Hf), zirconium (Zr), and oxygen (O). In other words, hafnium zirconium oxide may be represented by HfxZryO, with various combinations of numerical values of x, y and z instead of being represented by HfZrO₄.

The ferroelectric material film may further contain doped dopants. For example, the dopant may include at least one of, for example, aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr) or tin (Sn). A type of the dopant contained in the ferroelectric material film may vary depending on a type of the ferroelectric material included in the ferroelectric material film.

When the ferroelectric material film includes hafnium oxide (HfO₂), the dopant contained in the ferroelectric material film may include, for example, at least one of gadolinium (Gd), silicon (Si), zirconium (Zr), aluminum (Al), or yttrium (Y). However, the present disclosure is not limited thereto. For example, other dopants such as, for example, strontium (Sr), lanthanum (La), titanium (Ti) and tantalum (Ta) may also be used to dope the ferroelectric material layer including hafnium oxide (HfO₂).

When the dopant is aluminum (Al), the ferroelectric material film may contain about 3 to about 8 at % (atomic %) of aluminum (Al). In this case, a content of the dopant may be a content of aluminum (Al) based on a sum of hafnium (Hf) and aluminum (Al).

When the dopant is silicon (Si), the ferroelectric material film may contain about 2 to about 10 at % of silicon (Si). When the dopant is yttrium (Y), the ferroelectric material film may contain about 2 to about 10 at % yttrium (Y). When the dopant is gadolinium (Gd), the ferroelectric material film may contain about 1 to about 7 at % gadolinium (Gd). When the dopant is zirconium (Zr), the ferroelectric material film may contain about 50 to about 80 at % zirconium (Zr).

The paraelectric material film may have paraelectric properties. The paraelectric material film may include, for example, at least one of silicon oxide (SiO₂) or metal oxide having a high dielectric constant. The metal oxide contained in the paraelectric material film may include, for example, at least one of hafnium oxide (HfO₂), barium strontium titanium oxide (BaSrTi₂O₆), zirconium oxide (ZrO₂), or aluminum oxide (Al₂O₃). However, the present disclosure is not limited thereto.

The ferroelectric material film and the paraelectric material film may include the same material. The ferroelectric material film may have ferroelectric properties, but the paraelectric material film may not have the ferroelectric properties. For example, when each of the ferroelectric material film and the paraelectric material film includes hafnium oxide (HfO₂), a crystal structure of hafnium oxide (HfO₂) contained in the ferroelectric material film is different from a crystal structure of hafnium oxide (HfO₂) contained in the paraelectric material film.

The ferroelectric material film may exhibit ferroelectric properties, when its thickness is in a specific range. Although the thickness of the ferroelectric material film may be, for example, in a range of about 0.5 to about 10 nm, the present disclosure is not limited thereto. Because a critical thickness exhibiting the ferroelectric properties varies based on a type of the ferroelectric material, the thickness of the ferroelectric material film may vary depending on the type of the ferroelectric material.

In one example, the gate insulating film 130 may include one ferroelectric material film. In another example, the gate insulating film 130 may include a plurality of ferroelectric material films spaced apart from each other. The gate insulating film 130 may have a multilayer structure in which a plurality of ferroelectric material films and a plurality of paraelectric material films are alternately stacked on top of each other.

Each of a plurality of first gate capping films 145 may be disposed on an upper surface of each of the plurality of gate electrodes 120 and an upper surface of each of the plurality of gate spacers 140. For example, each of the first gate capping films 145 may extend along the upper surface of each of the plurality of gate electrodes 120 and the upper surface of each of the plurality of gate spacers 140. Each of the plurality of the first gate capping films 145 may include, for example, at least one of silicon nitride (Si₃N₄), silicon oxynitride (SiON), silicon oxide (SiO₂), silicon carbonitride (SiCN), silicon oxycarbonitride (SiOCN), or combinations thereof.

The source/drain pattern 150 may be disposed on the substrate 100. The source/drain pattern 150 may be formed on the first active pattern AP1. The source/drain pattern 150 is connected to the first active pattern AP1. For example, a bottom surface of the source/drain pattern 150 contacts the first active pattern AP1.

The source/drain pattern 150 may be disposed on sidewalls of each of the plurality of gate electrodes 120, and spaced apart from the plurality of gate electrodes. The source/drain pattern 150 may be disposed between adjacent ones of the plurality of gate electrodes 120. For example, the source/drain pattern 150 may be electrically insulated from the plurality of gate electrodes 120 via the gate insulating film 130 and/or the gate spacer 140.

The source/drain pattern 150 may be disposed on each of both opposing sides of each of the plurality of gate electrodes 120. Unlike what is illustrated, the source/drain pattern 150 may be disposed on one side of each of the plurality of gate electrodes 120 and may not be disposed on the other side of each of the plurality of gate electrodes 120.

The source/drain pattern 150 may include an epitaxial pattern. The source/drain pattern 150 may include a semiconductor material. The source/drain pattern 150 may be included in a source/drain of a transistor using the first active pattern AP1 as a channel area.

The source/drain pattern 150 may be connected to a channel area of the first active pattern AP1 used as a channel. It is illustrated that the source/drain pattern 150 is a merged structure of three epitaxial patterns respectively formed on three first active patterns AP1. However, the present disclosure is not limited thereto. For example, the epitaxial patterns respectively formed on the first active patterns AP1 may be isolated from each other. For example, the source/drain pattern 150 may be an epitaxial layer grown on the first active patterns AP1 using an epitaxial growth scheme. In an embodiment of the present disclosure, the source/drain pattern 150 may be formed by a selective epitaxial growth (SEG) process.

The source/drain pattern 150 may contain p-type impurities. For example, the source/drain pattern 150 may contain at least one of, for example, boron (B), carbon (C), indium (In), gallium (Ga), aluminum (Al), or combinations thereof. Alternatively, the source/drain pattern 150 may contain n-type impurities. For example, the source/drain pattern 150 may contain at least one of, for example, phosphorus (P), antimony (Sb), arsenic (As), bismuth (Bi) or combinations thereof.

In one example, an air gap may be disposed in a space between the merged source/drain pattern 150 and the field insulating film 105. In another example, an insulating material may fill a space between the merged source/drain pattern 150 and the field insulating film 105.

Similarly, the above-described source/drain pattern may be disposed on the second active pattern AP2 and between adjacent ones of the plurality of gate electrodes 120.

An etch stop film 160 may extend along the upper surface of the field insulating film 105, a sidewall of each of the plurality of gate spacers 140, and a profile of the source/drain pattern 150. The etch stop film 160 may be disposed on an upper surface of the source/drain pattern 150, a sidewall of the source/drain pattern 150, and a sidewall of each of the plurality of gate spacers 140. In an embodiment of the preset disclosure, the etch stop film 160 is not disposed on a sidewall of the first gate capping film 145. That is, the first gate capping film 145 may be disposed on an upper surface of the etch stop film 160. Further, a sidewall of the etch stop film 160 may be connected to an outer sidewall of the first gate capping film 145. To be described, a liner film 165 in contact with a sidewall of the first gate capping film 145 may contact the etch stop film 160.

The etch stop film 160 may include a material having an etch selectivity with respect to that of a first interlayer insulating film 190 to be described later. The etch stop film 160 may include a nitride-based insulating material. For example, the etch stop film 160 may include at least one of, for example, silicon nitride (Si₃N₄), silicon oxynitride (SiON), silicon oxycarbonitride (SiOCN), silicon boron nitride (SiBN), silicon oxyboronitride (SiOBN), or combinations thereof.

The first interlayer insulating film 190 is disposed on the etch stop film 160. The first interlayer insulating film 190 may be formed on the field insulating film 105. The first interlayer insulating film 190 may be disposed on the source/drain pattern 150. The first interlayer insulating film 190 may not cover an upper surface 145US of the first gate capping film 145. For example, an upper surface of the first interlayer insulating film 190 may be coplanar with the upper surface 145US of the first gate capping film 145. In an embodiment of the present disclosure, the first interlayer insulating film 190 may include a contact trench 170t. The contact trench 170t may expose the source/drain pattern 150. A contact silicide layer 155 may be disposed on a bottom surface of the contact trench 170t. The silicide layer may include a metal such as, for example, platinum (Pt), titanium (Ti), nickel (Ni), or cobalt (Co) to react with silicon (Si) to form a metal silicide such as, for example, platinum silicide (PtSi), titanium silicide (TiSi₂), nickel silicide (NiSi₂), or cobalt silicide (CoSi₂). Alternatively, the silicide layer 155 may include a metal such as, for example, aluminum (Al), tungsten (W), manganese (Mn), or molybdenum (Mo) to react with silicon (Si) to form a metal silicide such as, for example, aluminum silicide (Al₄Si₃), tungsten silicide (WSi₂), manganese silicide (MnSi₂), or molybdenum silicide (MoSi₂). However, the present disclosure is not limited thereto.

The first interlayer insulating film 190 may include, for example, at least one of silicon oxide (SiO₂), silicon nitride (Si₃N₄), silicon oxynitride, or a low dielectric constant (low-k) material. The low dielectric constant (low-k) material may include, for example, fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), Tonen SilaZen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or combinations thereof. However, the present disclosure is not limited thereto.

The first source/drain contact 170 may be disposed on the first active area RX1. A second source/drain contact 270 may be disposed on the second active area RX2. The first source/drain contact 170 may be connected to the source/drain pattern 150 formed in the first active area RX1. Similarly, the second source/drain contact 270 may be connected to a source/drain pattern formed in the second active area RX2.

Unlike what is illustrated, at least one of the first source/drain contacts 170 may be directly connected to at least one of the second source/drain contacts 270. For example, in the semiconductor device according to an embodiment of the present disclosure, at least one source/drain contact may be disposed continuously along the first active area RX1 and the second active area RX2. For example, the at least one source/drain contact may extend through the field area FX.

A description about the second source/drain contact 270 is substantially the same as a description about the first source/drain contact 170. Thus, following descriptions are about the first source/drain contact 170 disposed on the first active pattern AP1.

Each of the gate contacts 180 and 280 may be connected to at least one of the plurality of gate electrodes 120. Each of the gate contacts 180 and 280 may overlap each of the plurality of gate electrodes 120. In the semiconductor device according to an embodiment of the present disclosure, at least a portion of each of the gate contacts 180 and 280 may overlap at least one of the first active area RX1 and the second active area RX2.

In a plan view, an entirety of the gate contact 180 may overlap the first active area RX1. An entirety of the gate contact 280 may overlap the second active area RX2.

The first source/drain contact 170 may be disposed within the contact trench 170t. The first source/drain contact 170 may extend through the etch stop film 160, and thus may be connected to the source/drain pattern 150. The first source/drain contact 170 may be disposed on the source/drain pattern 150.

The first source/drain contact 170 may be disposed within the first interlayer insulating film 190, and may be surrounded with the first interlayer insulating film 190.

The contact silicide layer 155 may be disposed between the first source/drain contact 170 and the source/drain pattern 150. Although the contact silicide layer 155 is illustrated as being formed along a profile of a boundary surface between the source/drain pattern 150 and the first source/drain contact 170, the present disclosure is not limited thereto. The contact silicide layer 155 may include, for example, a metal silicide material. For example, the contact silicide layer 155 may be formed between the source/drain pattern 150 and the first source/drain contact 170 to provide reliable metal-semiconductor contact and reduce electrical resistance between the source/drain pattern 150 and the first source/drain contact 170.

The first interlayer insulating film 190 does not cover an upper surface 170US of the first source/drain contact 170. In one example, the upper surface 170US of the first source/drain contact 170 may not protrude upwardly beyond the upper surface 145US of the first gate capping film 145. The upper surface 170US of the first source/drain contact 170 may be coplanar with the upper surface 145US of the first gate capping film 145. Unlike what is illustrated, in another example, the upper surface 170US of the first source/drain contact 170 may protrude upwardly beyond the upper surface 145US of the first gate capping film 145. In this case, based on an upper surface of the substrate, a vertical level of the upper surface 170US of the first source/drain contact 170 is higher than a vertical level of the upper surface 145US of the first gate capping film 145.

In an embodiment of the present disclosure, the first source/drain contact 170 may include a source/drain barrier film 170BL and a source/drain filling film 170FL disposed on the source/drain barrier film 170BL. The source/drain barrier film 170BL may extend along an inner sidewall and a bottom surface of the contact trench 170t. The source/drain filling film 170FL may be disposed on the source/drain barrier film 170BL.

It is illustrated that a bottom surface 170BS of the first source/drain contact 170 has a curved shape convex toward the substrate 100. However, the present disclosure is not limited thereto. Unlike what is illustrated, in another example, the bottom surface 170BS of the first source/drain contact 170 may have a wavy shape or a flat shape.

The source/drain barrier film 170BL may include, for example, at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), or a two-dimensional (2D) material. In the semiconductor device according to an embodiment of the present disclosure, the 2D material may be a metallic material and/or a semiconductor material. The two-dimensional material (2D material) may include a two-dimensional allotrope or a two-dimensional compound. For example, the two-dimensional material (2D material) may include at least one of graphene, molybdenum disulfide (MoS₂), molybdenum diselenide (MoSe₂), tungsten diselenide (WSe₂), or tungsten disulfide (WS₂). However, the present disclosure is not limited thereto. For example, the above-mentioned 2D materials are only listed by way of example. The 2D material that may be included in the semiconductor device of the present disclosure is not limited to the above-mentioned materials. In an embodiment of the present disclosure, the source/drain barrier film 170BL may include two layers such as a metal layer and a metal nitride layer.

The source/drain filling film 170FL may include at least one of, for example, aluminum (Al), tungsten (W), cobalt (Co), ruthenium (Ru), silver (Ag), gold (Au), manganese (Mn), or molybdenum (Mo).

The first source/drain contact 170 is illustrated as including a plurality of conductive films. However, the present disclosure is not limited thereto. Unlike what is illustrated, the first source/drain contact 170 may be embodied as a single film.

A liner film 165 is disposed on the source/drain pattern 150. The liner film 165 may be disposed along an outer sidewall of the contact trench 170t. The liner film 165 may be disposed between the first source/drain contact 170 and the first interlayer insulating film 190. The liner film 165 may be disposed on the source/drain barrier film 170BL. For example, the liner film 165 may extend along a side surface of the first source/drain contact 170. The liner film 165 may contact the source/drain barrier film 170BL. For example, the liner film 165 may be interposed between the source/drain barrier film 170BL and the first interlayer insulating film 190. The liner film 165 does not extend along the bottom surface 170BS of the first source/drain contact 170. The liner film 165 may extend through the etch stop film 160. At least a portion of the liner film 165 may contact the source/drain pattern 150. At least a portion of the liner film 165 may be disposed in the source/drain pattern 150. Further, at least a portion of the liner film 165 may contact the contact silicide layer 155.

In an embodiment of the present disclosure, a thickness of the liner film 165 may be constant.

The liner film 165 may be formed using atomic layer deposition (ALD). Accordingly, the liner film 165 may be deposited so as to have a constant thickness.

In an embodiment of the present disclosure, the liner film 165 may contact the etch stop film 160. A sidewall of the liner film 165 may contact a sidewall of the etch stop film 160. Further, the liner film 165 may contact the first gate capping film 145. The sidewall of the liner film 165 may contact a sidewall 145SW of the first gate capping film 145.

The liner film 165 extends to the upper surface 145US of the first gate capping film 145. The liner film 165 extends to the upper surface 170US of the first source/drain contact 170. The topmost surface of the liner film 165 may be coplanar with the upper surface 145US of the first gate capping film 145 and the upper surface 170US of the first source/drain contact 170. Based on an upper surface of the substrate, a vertical level of a bottom surface 165BS of the liner film 165 is higher than a vertical level of a bottom surface 170BS of the first source/drain contact 170. The bottom surface 170BS of the first source/drain contact 170 may be convex downward toward the substrate 100.

In FIG. 2 and FIG. 3, a portion of the liner film 165 is in contact with the source/drain pattern 150. A portion of the liner film 165 may be disposed in the source/drain pattern 150.

The liner film 165 includes an oxide-based insulating material. For example, the liner film 165 may include an insulating material including carbon (C) and oxygen (O). For example, the liner film 165 may include, for example, silicon oxycarbide (SiOC).

Each of the gate contacts 180 and 280 may be disposed on the gate electrode 120. For convenience of illustration, only the gate contact 180 disposed on the first active area RX1 is described. The gate contact 180 may extend through the first gate capping film 145, and thus, may be connected to the gate electrode 120.

In one example, an upper surface 180US of the gate contact 180 may be coplanar with the upper surface 145US of the first gate capping film 145. Also, the upper surface 180US of the gate contact 180 may be coplanar with the upper surface 170US of the source/drain contact 170. Unlike what is illustrated, in another example, the upper surface 180US of the gate contact 180 may protrude upwardly beyond the upper surface 145US of the first gate capping film 145. In this case, based on the upper surface of the substrate, a vertical level of the upper surface 180US of the gate contact 180 is higher than a vertical level of the upper surface 145US of the first gate capping film 145.

The gate contact 180 may include a gate barrier film 180BL and a gate filling film 180FL disposed on the gate barrier film 180BL. A description about a material included in each of the gate barrier film 180BL and the gate filling film 180FL may be the same as the description about the material included in each of the source/drain barrier film 170BL and the source/drain filling film 170FL. In an embodiment of the present disclosure, the gate barrier film 180BL may include two layers such as a metal layer and a metal nitride layer.

A lower stop film 196 may be disposed on the first interlayer insulating film 190, the first gate capping film 145, the first source/drain contact 170 and the gate contact 180. A second interlayer insulating film 191 is disposed on the lower stop film 196.

The lower stop film 196 may include a material having an etch selectivity with respect to that of the second interlayer insulating film 191. The lower stop film 196 may include, for example, at least one of silicon nitride (Si₃N₄), silicon oxynitride (SiON), silicon oxycarbonitride (SiOCN), silicon boron nitride (SiBN), silicon oxyboronitride (SiOBN), silicon oxycarbide (SiOC), aluminum oxide (Al₂O₃), aluminum nitride (AlN), aluminum oxycarbide (AlOC), or combinations thereof. The lower stop film 196 is shown as being embodied as a single film. However, the present disclosure is not limited thereto. Unlike what is illustrated, the lower stop film 196 may not be formed. The second interlayer insulating film 191 may include, for example, at least one of silicon oxide (SiO₂), silicon nitride (Si₃N₄), silicon carbonitride (SiCN), silicon oxynitride (SiON), or a low dielectric constant (low-k) material.

The via plug 210 may be disposed within the second interlayer insulating film 191. The via plug 210 may extend through the lower stop film 196, and thus, may be directly connected to the first source/drain contact 170 and/or the gate contact 180.

The via plug 210 may include a via barrier film 210BL and a via filling film 210FL. The via barrier film 210BL may extend along a sidewall and a bottom surface of the via filling film 210BL. The via barrier film 210BL may include, for example, at least one of tantalum (Ta), tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), or a two-dimensional material (2D material). The via filling film 210FL may include, for example, at least one of aluminum (Al), tungsten (W), cobalt (Co), ruthenium (Ru), copper (Cu), silver (Ag), gold (Au), manganese (Mn), or molybdenum (Mo).

An upper stop film 197 may be disposed between the second interlayer insulating film 191 and a third interlayer insulating film 192. The upper stop film 197 may extend along an upper surface of the second interlayer insulating film 191.

The upper stop film 197 may include a material having an etch selectivity with respect to that of the third interlayer insulating film 192. A description about the material included in the upper stop film 197 may be the same as the description about the material of the lower stop film 196. The upper stop film 197 is illustrated as being embodied as a single film. However, the present disclosure is not limited thereto. Unlike what is illustrated, the upper stop film 197 may not be formed. The third interlayer insulating film 192 may include, for example, at least one of silicon oxide (SiO₂), silicon nitride (Si₃N₄), silicon carbonitride (SiCN), silicon oxynitride (SiON), or a low dielectric constant (low-k) material.

The wiring line 220 may be disposed within the third interlayer insulating film 192. The wiring line 220 is connected to the via plug 210. For example, the wiring line 220 may contact the via plug 210, and may be electrically connected to the via plug 210.

The wiring line 220 may include a wiring barrier film 220BL and a wiring filling film 220FL. The wiring barrier film 220BL may include, for example, at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), or a two-dimensional material (2D material). The wiring filling film 207b may include, for example, at least one of aluminum (Al), copper (Cu), tungsten (W), cobalt (Co), ruthenium (Ru), silver (Ag), gold (Au), manganese (Mn), or molybdenum (Mo).

Unlike what is illustrated, the wiring barrier film 220BL may not be disposed between the via filling film 210FL and the wiring filling film 220FL. A first connection contact connecting the via plug 210 and the first source/drain contact 170 to each other may be further disposed between the via plug 210 and the first source/drain contact 170. Further, a second connection contact connecting the via plug 210 and the gate contact 180 to each other may be further disposed between the via plug 210 and the gate contact 180.

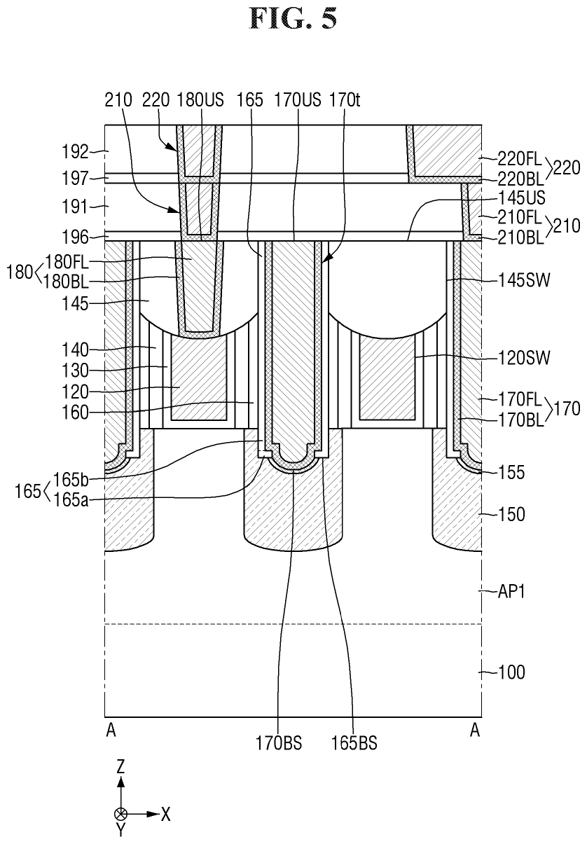

Hereinafter, a semiconductor device according to an embodiment of the present disclosure will be described with reference to FIG. 5 to FIG. 17. For the convenience of description, following description is based on differences from those as set forth above with reference to FIG. 1 to FIG. 4.

FIG. 5 to FIG. 8 are diagrams each for illustrating a semiconductor device according to an embodiment of the present disclosure.

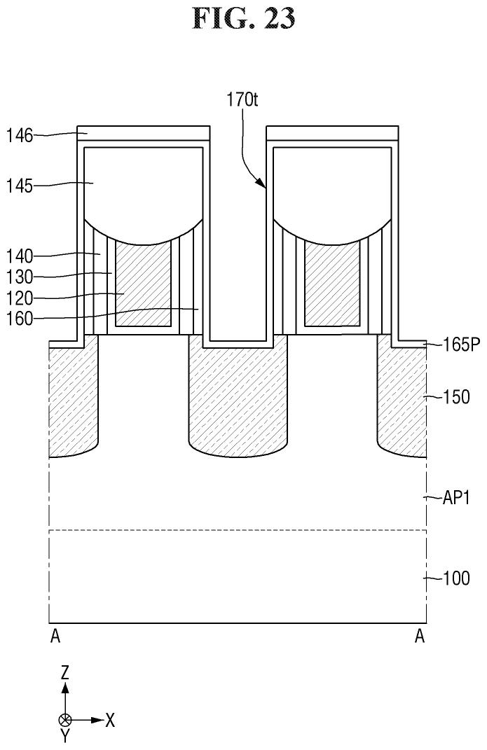

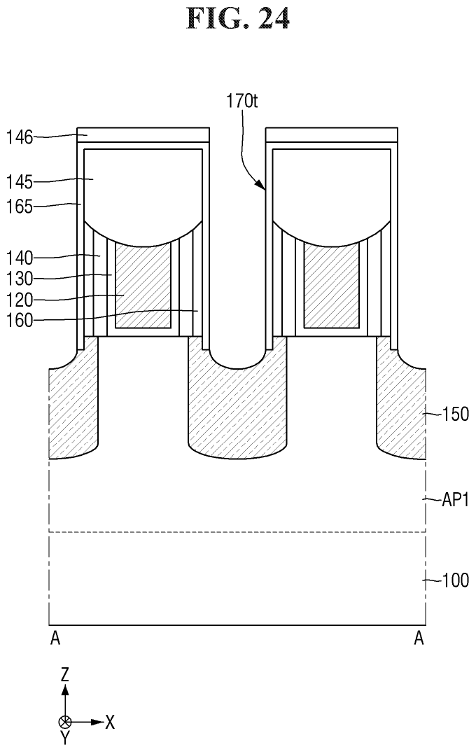

First, referring to FIG. 5, the liner film 165 according to an embodiment of the present disclosure may include a first portion 165a and a second portion 165b disposed on the first portion 165a. In a cross-sectional view, the first portion 165a of the liner film 165 may extend in the first direction X. The second portion 165b of the liner film 165 may extend in the third direction Z. The first portion 165a of the liner film 165 may extend in the second direction Y. In a process of forming the contact trench 170t, the first portion 165a of the liner film 165 may not be entirely removed. To be described, the liner film 165 may be formed by removing a portion of a pre-liner film 165P to expose a portion of the source/drain pattern 150 within the contact trench 170t (see FIGS. 23 and 24). The first portion 165a of the liner film 165 may be some bottom portion of the pre-liner film 165P not removed during the etching process. Accordingly, a shape of the liner film 165 in the cross-sectional view may be an ‘L’ shape.

The source/drain contact barrier film 170BL may be disposed along a profile of each of the second portion 165b and the first portion 165a of the liner film 165. Accordingly, at a boundary between the second portion 165b and the first portion 165a of the liner film 165, the source/drain contact barrier film 170BL may have a step.

The bottom surface 165BS of the liner film 165 may contact the source/drain pattern 150. In an embodiment of the present disclosure, based on the upper surface of the substrate, a vertical level of the bottom surface 165BS of the liner film 165 is higher than a vertical level of the bottom surface 170BS of the first source/drain contact 170. However, the present disclosure is not limited thereto.

In an embodiment of the present disclosure, at least a portion of the contact silicide layer 155 may contact the first portion 165a of the liner film 165. However, the present disclosure is not limited thereto. The contact silicide layer 155 may be formed along a profile of a boundary surface between the source/drain pattern 150 and the first source/drain contact 170 to provide reliable metal-semiconductor contact and reduce electrical resistance between the source/drain pattern 150 and the first source/drain contact 170.

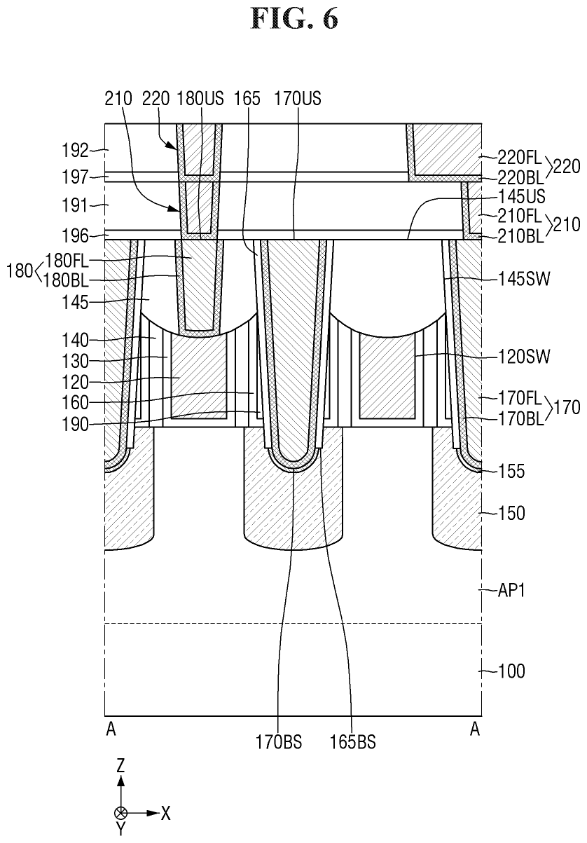

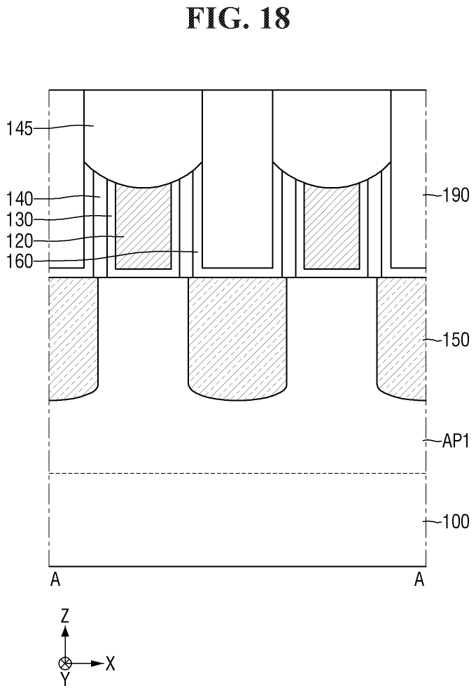

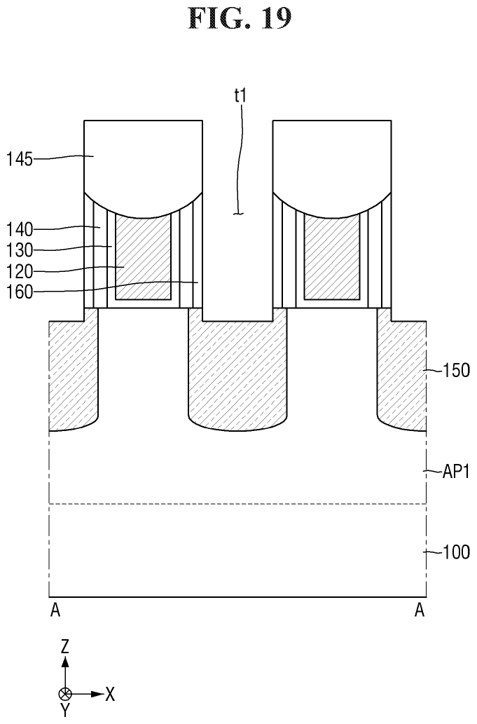

Referring to FIG. 6, a width in the first direction X of the first gate capping film 145 may gradually decrease as the first gate capping film 145 extends away from the upper surface of the gate electrode 120 in the third direction Z. This may be because a portion of the first gate capping film 145 is etched in a process of forming the contact trench 170t. To be described, referring to FIG. 19, a first trench t1 may be formed using the first gate capping film 145 as an etching mask to selectively remove the first interlayer insulating film 190 between adjacent ones of the plurality of gate electrodes 120 (see FIGS. 18 and 19). The first gate capping film 145 may be partially removed during the etching process to form a sloped sidewall profile. Further, in a cross-sectional view, a shape of the etch stop film 160 may be an ‘L’ shape. The first interlayer insulating film 190 may be disposed between the etch stop film 160 and the liner film 165. However, the present disclosure is not limited thereto.

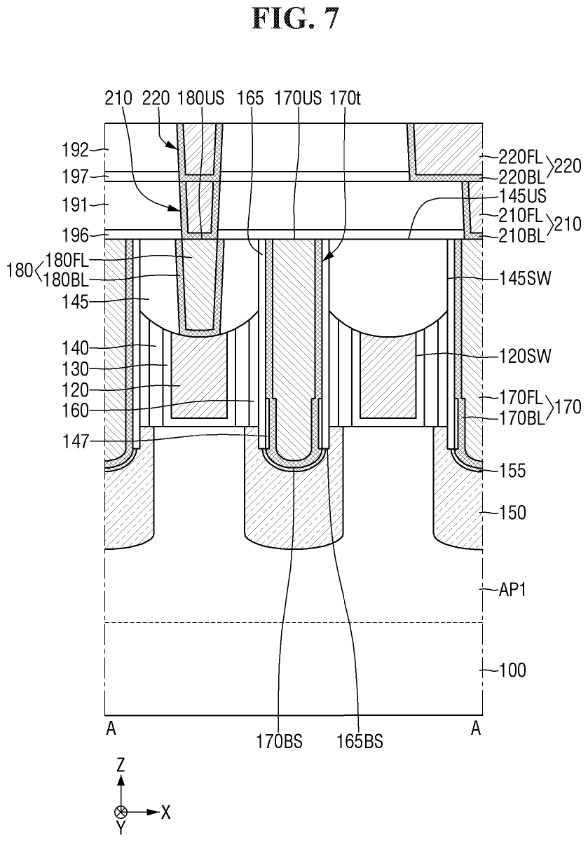

Referring to FIG. 7, a semiconductor device according to an embodiment of the present disclosure may further include a residue layer 147.

The residue layer 147 may be disposed on a portion of a sidewall of the liner film 165. The residue layer 147 may be disposed adjacent to the source/drain pattern 150. At least a portion of the residue layer 147 may overlap the plurality of gate electrodes 120, the plurality of gate spacers 140, and the etch stop film 160 in the first direction X. The residue layer 147 may not overlap with the first gate capping film 145 in the first direction X. Unlike what is illustrated, in another example, the residue layer 147 may overlap the first gate capping film 145 in the first direction X.

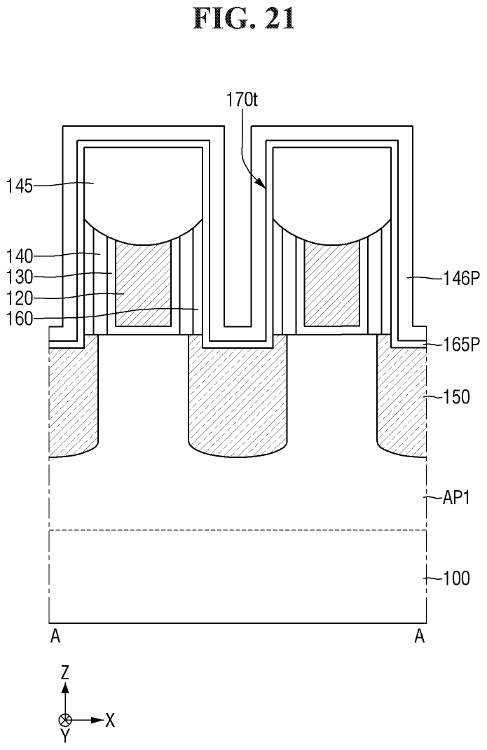

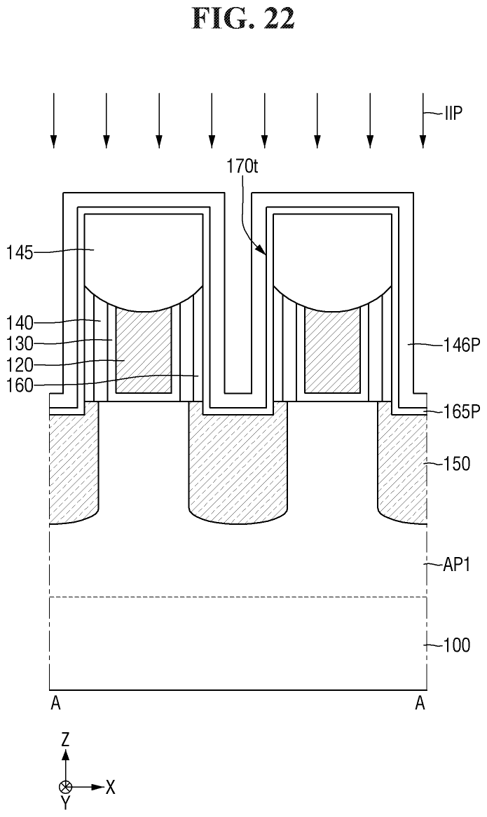

A thickness of the residue layer 147 may be smaller than a thickness of the liner film 165. The residue layer 147 may be made of a residue of a compensation insulating film (146P in FIG. 21). The compensation insulating film will be described in detail using FIG. 21. To be described, a portion of the compensation insulating film 146P disposed on the sidewall of the pre-liner film 165P and the portion of the compensation insulating film 146P disposed on the source/drain pattern 150 may be selectively removed (see FIGS. 22 and 23). The residue layer 147 may be some portion of the compensation insulating film 146P on the sidewall of the pre-liner film 165P not removed during the etching process. The residue layer 147 may include a nitride-based insulating material. In an embodiment of the present disclosure, a material included in the residue layer 147 may be the same as the material included in the first gate capping film 145. However, the present disclosure is not limited thereto. For example, the residue layer 147 may include, for example, at least one of silicon nitride (Si₃N₄), silicon oxynitride (SiON), silicon carbonitride (SiCN), silicon oxycarbonitride (SiOCN), or combinations thereof.

In an embodiment of the present disclosure, the source/drain barrier film 170BL may be formed along a profile of each of the liner film 165 and the residue layer 147. For example, a step may occur between a portion of the source/drain barrier film 170BL on which the residue layer 147 is not disposed and a portion of the source/drain barrier film 170BL on which the residue layer 147 is disposed. However, the present disclosure is not limited thereto.

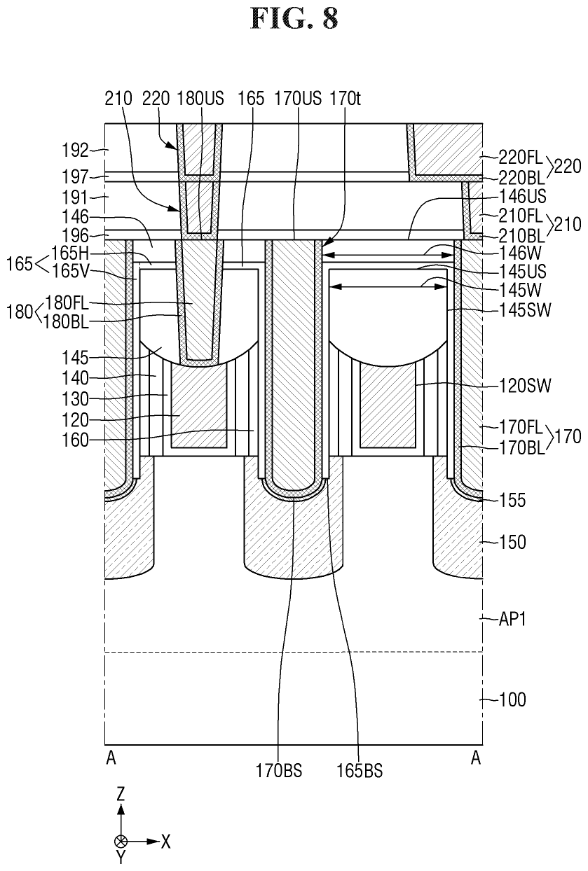

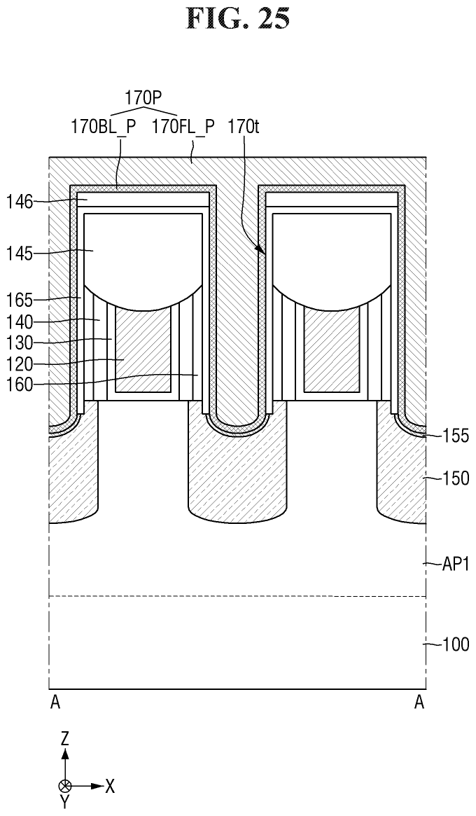

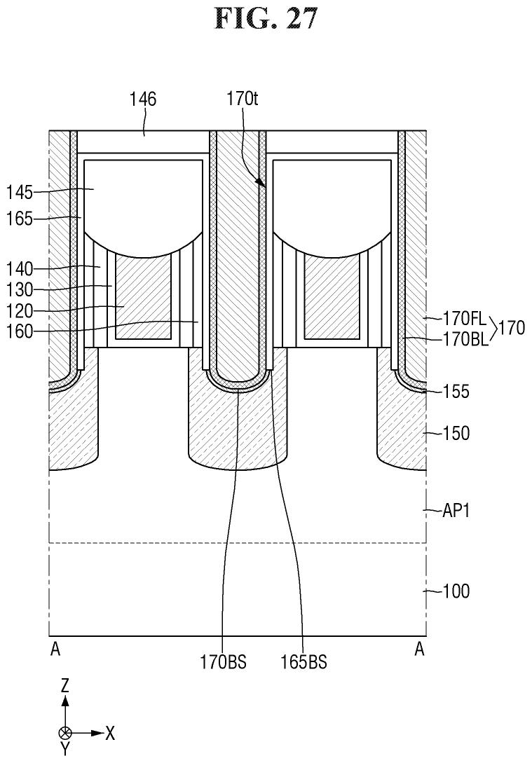

Referring to FIG. 8, a semiconductor device according to an embodiment of the present disclosure may further include a second gate capping film 146. Further, in the semiconductor device according to an embodiment of the present disclosure, the liner film 165 may include a horizontal portion 165H and a vertical portion 165V. To be described, during the formation of the first source/drain contact 170 via a planarization process (CMP; Chemical Mechanical Polishing), the second gate capping film 146 may not be removed (see FIGS. 25 and 27). In this regard, the liner film 165 may be disposed between the first gate capping film 145 and the second gate capping film 146.

The horizontal portion 165H of the liner film 165 may extend along the upper surface 145US of the first gate capping film 145. The vertical portion 165V of the liner film 165 may extend along the sidewall 145SW of the first gate capping film 145 and a sidewall of the etch stop film 160. The vertical portion 165V of the liner film 165 may extend along a portion of the outer sidewall of the contact trench 170t. The vertical portion 165V of the liner film 165 does not extend to the upper surface 170US of the first source/drain contact 170. The vertical portion 165V of the liner film 165 does not protrude upwardly beyond the upper surface 145US of the first gate capping film 145. At least a portion of the vertical portion 165V of the liner film 165 may not overlap with the first source/drain contact 170 in the first direction X. The vertical portion 165V of the liner film 165 may not overlap the second gate capping film 146 in the first direction X.

The second gate capping film 146 may be disposed on the horizontal portion 165H of the liner film 165. The second gate capping film 146 may entirely overlap the first gate capping film 145 in the third direction Z. In an embodiment of the present disclosure, a width 146W in the first direction X of the second gate capping film 146 is greater than a width 145W in the first direction X of the first gate capping film 145. This may be because a width in the first direction X of the horizontal portion 165H of the liner film 165 is greater than the width 145W of the first gate capping film 145.

In an embodiment of the present disclosure, an upper surface 146US of the second gate capping film 146 is coplanar with the upper surface 170US of the first source/drain contact 170. Further, the upper surface 146US of the second gate capping film 146 is coplanar with an upper surface 180US of the gate contact 180 and the upper surface of the first interlayer insulating film 190. Based on the upper surface of the substrate, a vertical level of the upper surface 170US of the first source/drain contact 170 is higher than a vertical level of each of an upper surface of the liner film 165 and the upper surface 145US of the first gate capping film 145.

In an embodiment of the present disclosure, the gate contact 180 may extend through the second gate capping film 146, the horizontal portion 165H of the liner film 165, and the first gate capping film 145, and thus, may be connected to one of some of the plurality of gate electrodes 120. This is because some of the plurality of gate electrodes 120 may not be connected to the gate contact 180, but may be connected to the gate contact 280.

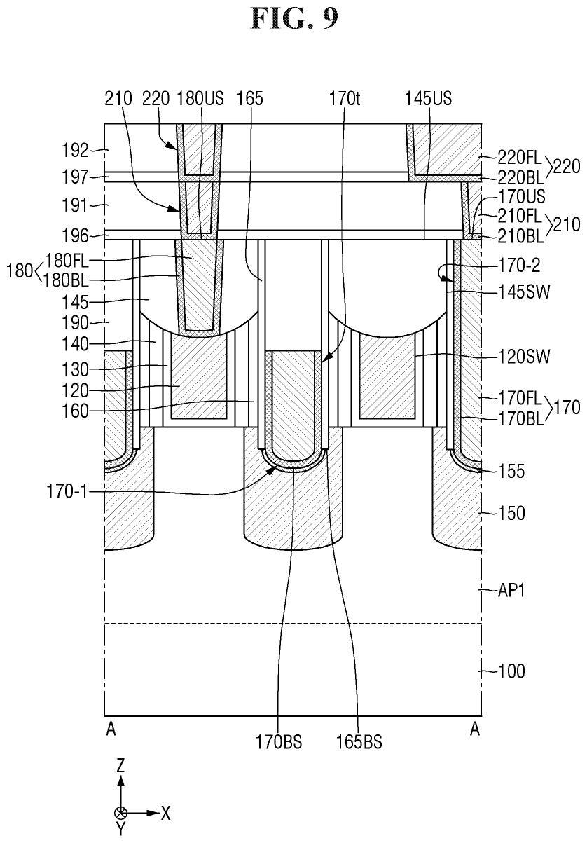

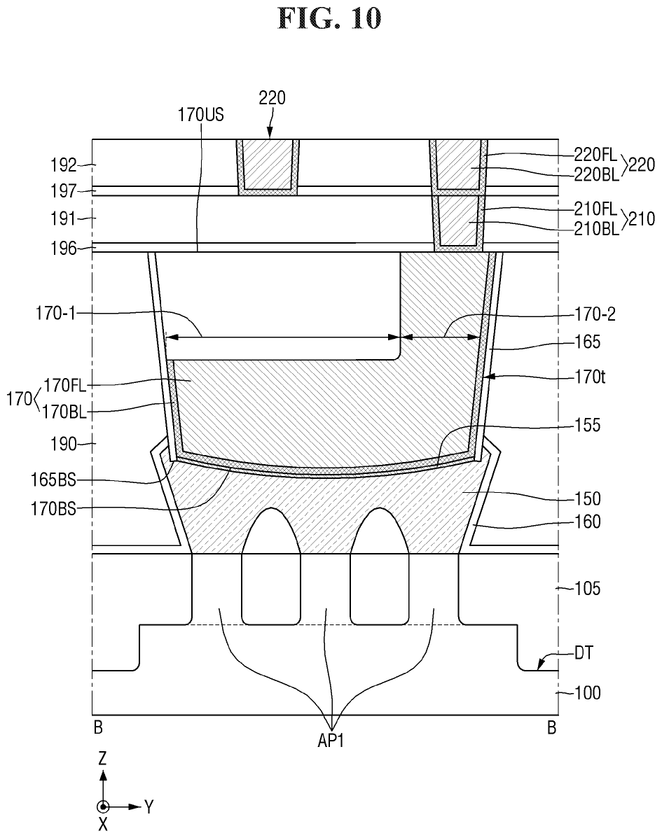

FIG. 9 and FIG. 10 are diagrams for illustrating a semiconductor device according to an embodiment of the present disclosure.

Referring to FIG. 9 and FIG. 10, in the semiconductor device according to an embodiment of the present disclosure, the first source/drain contact 170 may include a first portion 170-1 and a second portion 170-2.

The first portion 170-1 of the first source/drain contact 170 may be directly connected to the second portion 170-2 of the first source/drain contact 170.

The second portion 170-2 of the first source/drain contact 170 is a portion on which the via plug 210 lands. The first source/drain contact 170 may be connected to the wiring line 220 via the second portion 170-2 of the first source/drain contact 170. The first portion 170-1 of the first source/drain contact 170 is not a portion on which the via plug 210 lands.

In a cross-sectional view shown in FIG. 9, the second portion 170-2 of the first source/drain contact 170 may be disposed so as to be connected to the via plug 210. The first portion 170-1 of the first source/drain contact 170 may be disposed so as not to be connected to the via plug 210.

Further, to prevent a short-circuit between the gate contact 180 and the first source/drain contact 170, the first portion 170-1 of the first source/drain contact 170 may be disposed on each of both opposing sides of a portion of the gate electrode 120 connected to the gate contact 180, while the second portion 170-2 of the first source/drain contact 170 may not be disposed on each of both opposing sides of the portion of the gate electrode 120 connected to the gate contact 180. For example, in a cross-sectional view shown in FIG. 9, the first portion 170-1 of the first source/drain contact 170 may be disposed on each of both opposing sides of the portion of the gate electrode 120 connected to the gate contact 180, while the second portion 170-2 of the first source/drain contact 170 may not be disposed on each of both opposing sides of the portion of the gate electrode 120 connected to the gate contact 180.

A vertical level of an upper surface of the second portion 170-2 of the first source/drain contact 170 is higher than a vertical level of an upper surface of the first portion 170-1 of the first source/drain contact 170. In FIG. 10, based on the upper surface of the field insulating film 105, a vertical level of the upper surface of the second portion 170-2 of the first source/drain contact 170 is higher than a vertical level of the upper surface of the first portion 170-1 of the first source/drain contact 170. For example, the upper surface 170US of the first source/drain contact 170 may be the upper surface of the second portion 170-2 of the first source/drain contact 170.

In FIG. 10, the first source/drain contact 170 is shown as having an ‘L’ shape. However, the present disclosure is not limited thereto. Unlike what is illustrated, the first source/drain contact 170 may have an inverted T-shape. In this case, the first portion 170-1 of the first source/drain contact 170 may be disposed on each of both opposing sides of the second portion 170-2 of the first source/drain contact 170.

The liner film 165 protrudes in the third direction Z beyond the upper surface of the first portion 170-1 of the first source/drain contact 170. The liner film 165 may be disposed on a sidewall of the second portion 170-2 of the first source/drain contact 170. For example, the first interlayer insulating film 190 may be disposed between the liner film 165 and the second portion 170-2 of the first source/drain contact 170. The first interlayer insulating film 190 may cover the upper surface of the first portion 170-1 of the first source/drain contact 170. For example, the first interlayer insulating film 190 may be disposed in the contact trench 170t within a space not occupied by the first source/drain contact 170, for example, a space above the first portion 170-1 of the first source/drain contact 170.

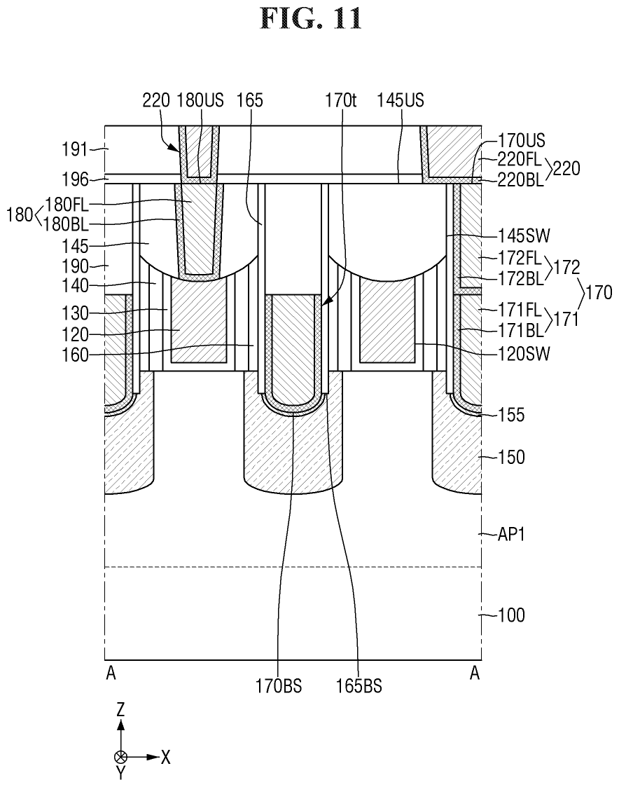

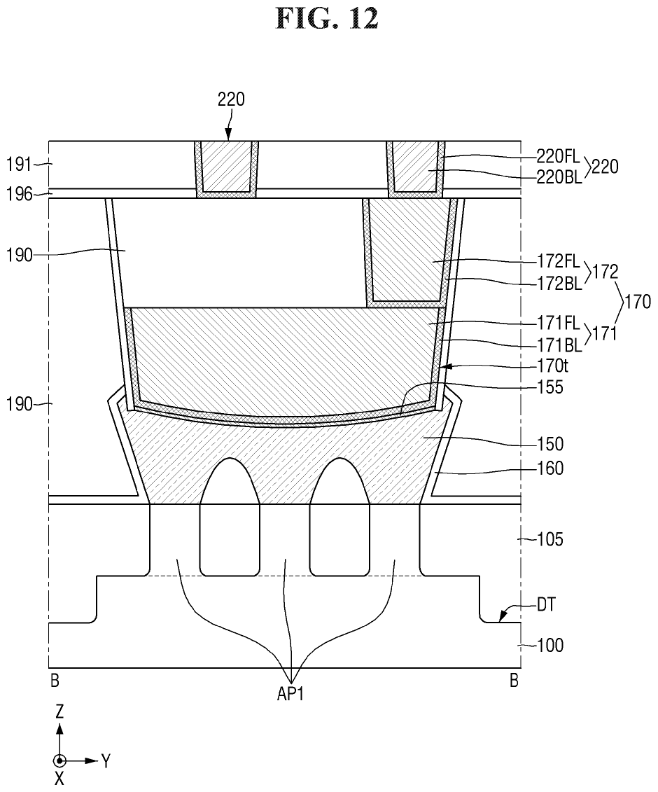

FIG. 11 and FIG. 12 are diagrams for illustrating a semiconductor device according to an embodiment of the present disclosure.

Referring to FIG. 11 and FIG. 12, in the semiconductor device according to an embodiment of the present disclosure, the first source/drain contact 170 may include a lower source/drain contact 171 and an upper source/drain contact 172.

The lower source/drain contact 171 may include a lower source/drain barrier film 171BL and a lower source/drain filling film 171FL. The upper source/drain contact 172 may include an upper source/drain barrier film 172BL and an upper source/drain filling film 172FL.

The upper surface of the first source/drain contact 170 may be an upper surface of the upper source/drain contact 172. A description about a material included in each of the lower source/drain barrier film 171BL and the upper source/drain barrier film 172BL may be the same as the description about the material of the source/drain barrier film 170BL. A description about a material included in each of the lower source/drain filling film 171FL and the upper source/drain filling film 172FL may be the same as the description about the material of the source/drain filling film 170FL. Unlike what is illustrated, the upper source/drain contact 172 may be embodied as a single film. The first interlayer insulating film 190 may be disposed between the liner film 165 and the upper source/drain contact 172. The first interlayer insulating film 190 may cover a portion of the upper surface of the lower source/drain contact 171. For example, the first interlayer insulating film 190 may be disposed in the contact trench 170t within a space not occupied by the first source/drain contact 170, for example, a space over a portion of the lower source/drain contact 171.

The wiring line 220 may be connected to the first source/drain contact 170 and the gate contact 180 without the via plug (210 in FIG. 2). The wiring line 220 may be disposed in the lower stop film 196 and the second interlayer insulating film 191.

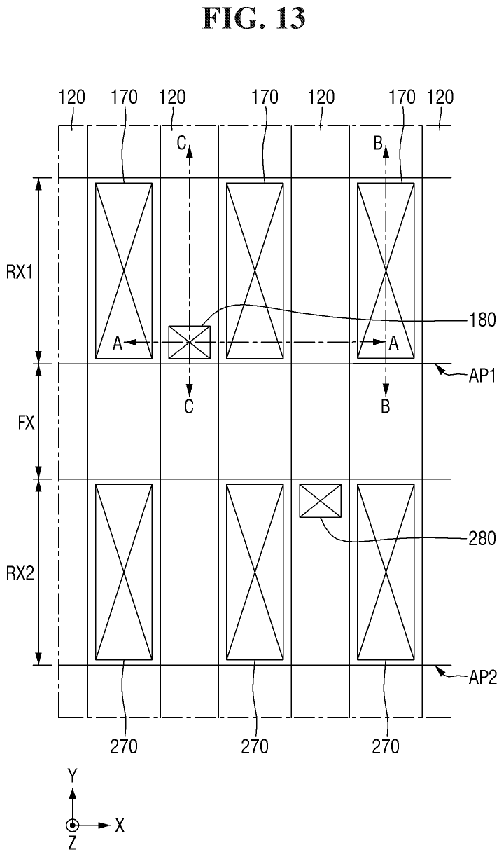

FIG. 13 to FIG. 17 are diagrams for illustrating a semiconductor device according to an embodiment of the present disclosure.

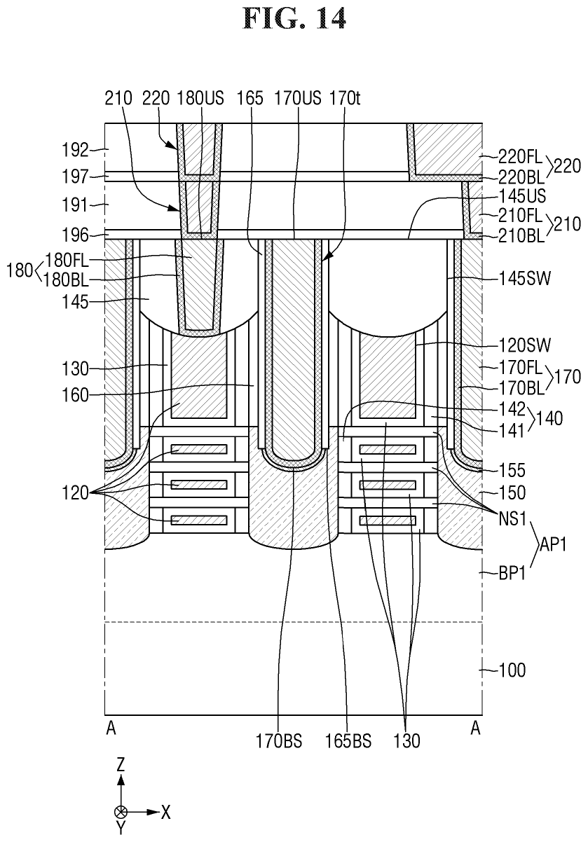

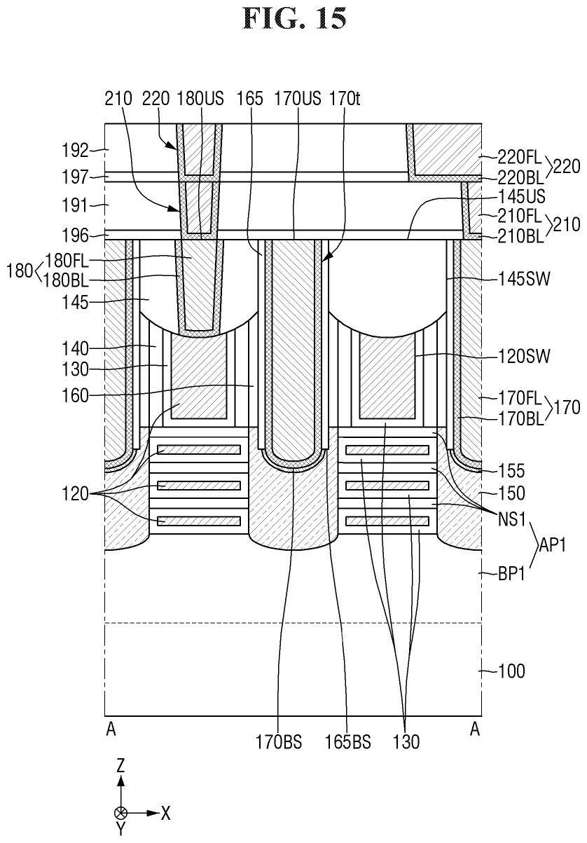

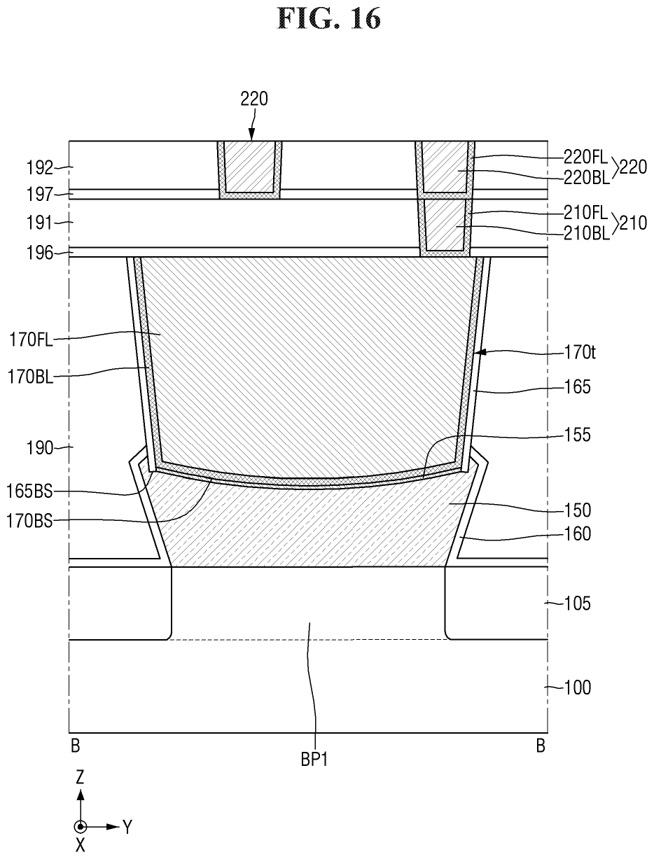

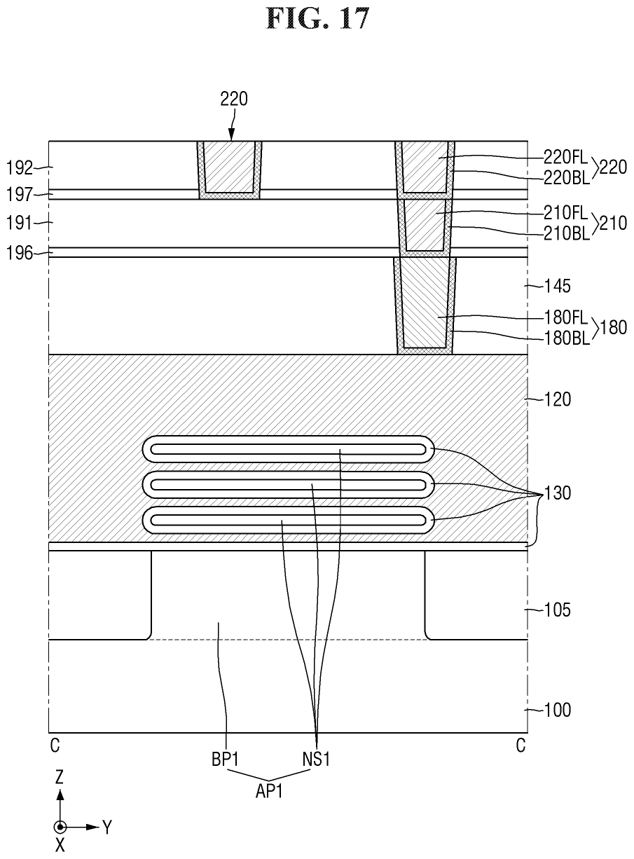

FIG. 13 to FIG. 17 are diagrams for illustrating a semiconductor device according to an embodiment of the present disclosure. FIG. 13 is an illustrative layout diagram for illustrating a semiconductor device according to an embodiment of the present disclosure. FIGS. 14 and 15 are illustrative cross-sectional views taken along line A-A of FIG. 13, respectively. FIG. 16 is a cross-sectional view taken along line B-B in FIG. 13. FIG. 17 is a cross-sectional view taken along line C-C in FIG. 13. For convenience of description, following description is based on differences from those as set forth above with reference to FIG. 1 to FIG. 4.

Referring to FIG. 13 to FIG. 17, in the semiconductor device according to an embodiment of the present disclosure, the first active pattern AP1 may include a lower pattern BP1 and at least one sheet pattern NS1.

Similarly, the second active pattern AP2 may include a lower pattern and a sheet pattern.

The lower pattern BP1 may extend along the first direction X. The sheet pattern NS1 may be disposed on the lower pattern BP1 and may be spaced apart from the lower pattern BP1.

The sheet pattern NS1 may include a plurality of sheet patterns stacked in the third direction Z. Although it is illustrated that three sheet patterns NS1 are stacked, this is intended only for convenience of illustration, and the present disclosure is not limited thereto. For example, the number of sheet patterns NS1 may be one, two or more than three. An upper surface of the topmost sheet pattern NS1 among the sheet patterns NS1 may be an upper surface of the first active pattern AP1.

The sheet pattern NS1 may be connected to the source/drain pattern 150. The sheet pattern NS1 may be a channel pattern used as a channel area of a transistor. For example, the sheet pattern NS1 may be embodied as a nanosheet or a nanowire.

The lower pattern BP1 may include, for example, silicon (Si) or germanium (Ge) which is an elemental semiconductor material. Alternatively, the lower pattern BP1 may include a compound semiconductor. For example, the lower pattern BP1 may include a group IV-IV compound semiconductor or a group III-V compound semiconductor.

The sheet pattern NS1 may include, for example, silicon (Si) or germanium (Ge) which is an elemental semiconductor material. Alternatively, the sheet pattern NS1 may include a compound semiconductor. For example, the sheet pattern NS1 may include a group IV-IV compound semiconductor or a group III-V compound semiconductor.

The gate insulating film 130 may extend along an upper surface of the lower pattern BP1 and the upper surface of the field insulating film 105. The gate insulating film 130 may surround the sheet pattern NS1.

The gate electrode 120 is disposed on the lower pattern BP1. The gate electrode 120 intersects the lower pattern BP1. The gate electrode 120 may surround the sheet pattern NS1. The gate electrode 120 may be disposed between the lower pattern BP1 and the bottommost sheet pattern NS1 and between adjacent sheet patterns NS1.

In FIG. 14, the gate spacer 140 may include an outer spacer 141 and an inner spacer 142. The inner spacer 142 may be disposed between the lower pattern BP1 and the bottommost sheet pattern NS1 and between adjacent sheet patterns NS1.

In FIG. 15, the gate spacer 140 may include only the outer spacer 141. No inner spacer is disposed between the lower pattern BP1 and the bottommost sheet pattern NS1 and between the adjacent sheet patterns NS1.

The bottom surface 170BS of the first source/drain contact 170 may be disposed between the upper surface of the bottommost sheet pattern NS1 among the plurality of sheet patterns NS1 and a bottom surface of the topmost sheet pattern NS1 among the plurality of sheet patterns NS1. Unlike what is illustrated, the bottom surface 170BS of the first source/drain contact 170 may be disposed between the upper surface of the topmost sheet pattern NS1 and a bottom surface of the topmost sheet pattern NS1.

The features illustrated in FIGS. 5-12 may also be applied to combine with the features of FIGS. 13-17. For example, unlike what is illustrated in FIGS. 13-17, the liner film 165 in FIG. 14 or FIG. 15 according to an embodiment of the present disclosure may include a first portion 165a and a second portion 165b disposed on the first portion 165a as illustrated in FIG. 5. For example, unlike what is illustrated in FIGS. 13-17, a width in the first direction X of the first gate capping film 145 in FIG. 14 or FIG. 15 according to an embodiment of the present disclosure may gradually decrease as the first gate capping film 145 extends away from the upper surface of the gate electrode 120 in the third direction Z as illustrated in FIG. 6. For example, unlike what is illustrated in FIGS. 13-17, the first source/drain contact 170 in FIG. 14 or FIG. 15 according to an embodiment of the present disclosure may have a residue layer 147 disposed on a portion of a sidewall of the liner film 165 as illustrated in FIG. 7. For example, unlike what is illustrated in FIGS. 13-17, a semiconductor device in FIG. 14 or FIG. 15 according to an embodiment of the present disclosure may further include a second gate capping film 146 as illustrated in FIG. 8. For example, unlike what is illustrated in FIGS. 13-17, the first source/drain contact 170 in FIG. 14 or FIG. 15 according to an embodiment of the present disclosure may include a first portion 170-1 and a second portion 170-2 as illustrated in FIG. 9. For example, unlike what is illustrated in FIGS. 13-17, the first source/drain contact 170 in FIG. 14 or FIG. 15 according to an embodiment of the present disclosure may include a lower source/drain contact 171 and an upper source/drain contact 172 as illustrated in FIG. 11.

FIG. 18 to FIG. 27 are diagrams of intermediate structures corresponding to intermediate steps for illustrating a method for manufacturing a semiconductor device according to an embodiment of the present disclosure. For reference, FIG. 18 to FIG. 27 may be cross-sectional views taken along line A-A in FIG. 1. Hereinafter, the manufacturing method is described based on a cross-sectional view.

Referring to FIG. 18, the source/drain pattern 150 may be formed on the first active pattern AP1.

The etch stop film 160 and the first interlayer insulating film 190 are sequentially formed on the source/drain pattern 150. The etch stop film 160 is formed along a profile of the source/drain pattern 150 and a sidewall of the gate spacer 140. The first interlayer insulating film 190 is formed on the etch stop film 160.

After the first interlayer insulating film 190 has been formed, the plurality of gate electrodes 120, the plurality of gate spacers 140, the plurality of gate insulating films 130, and the plurality of first gate capping films 145 may be formed via a replacement metal gate (RMG) process.

Referring to FIG. 19, a first trench t1 may be formed. The first trench t1 may be formed between adjacent ones of the plurality of gate electrodes 120. The first trench t1 may be formed using the first gate capping film 145 as an etching mask. For example, the first gate capping film 145 and the first interlayer insulating film 190 may have an etch selectivity relative to each other. Accordingly, the first interlayer insulating film 190 may be selectively removed. In an embodiment of the present disclosure, the first gate capping film 145 may be partially removed. Accordingly, a height in the third direction Z of the first gate capping film 145 may be reduced. An anisotropic etching process may be used in selectively removing the first interlayer insulating film 190, and thus, a portion of the etch stop film 160 overlapping the first interlayer insulating film 190 in the third direction Z may also be removed in the etching process. The first trench t1 may expose the source/drain pattern 150. The first trench t1 may extend through the etch stop film 160.

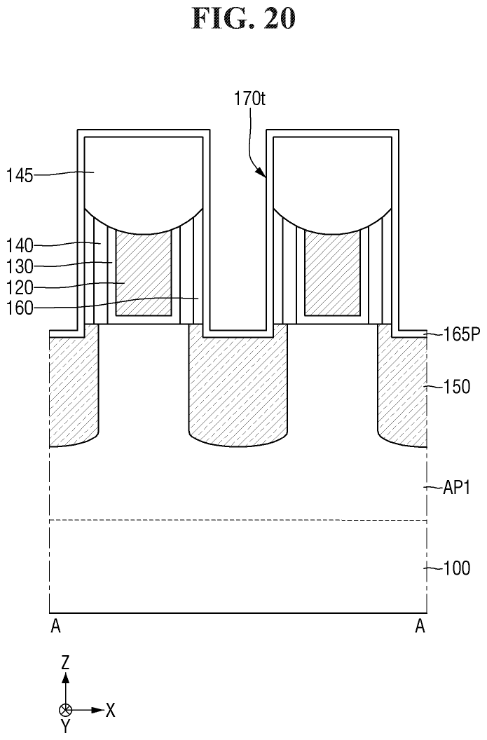

Referring to FIG. 20, a pre-liner film 165P may be formed. The pre-liner film 165P may be formed along a sidewall of the first trench t1 and a bottom surface of the first trench t1. For example, the pre-liner film 165P may extend along a profile of the source/drain pattern 150, a sidewall of the etch stop film 160, a sidewall of the first gate capping film 145, and an upper surface of the first gate capping film 145. A thickness of the pre-liner film 165P may be constant. For example, the pre-liner film 165P may be formed using atomic layer deposition (ALD). The pre-liner film 165P may be conformally deposited.

The pre-liner film 165P may define the contact trench 170t. In other words, the pre-liner film 165P may be disposed on an outer sidewall of the contact trench 170t. The first source/drain contact 170 to be described below may be disposed in the contact trench 170t.

The pre-liner film 165P includes an oxide-based insulating material. For example, the pre-liner film 165P may include an insulating material including carbon (C) and oxygen (O). For example, the pre-liner film 165P may include, for example, silicon oxycarbide (SiOC).

Referring to FIG. 21, the compensation insulating film 146P may be formed. The compensation insulating film 146P may be formed on the pre-liner film 165P. For example, the compensation insulating film 146P may be formed along a bottom surface of the contact trench 170t, a sidewall of the contact trench 170t, and an upper surface of the pre-liner film 165P. The compensation insulating film 146P may be formed using atomic layer deposition (ALD). The compensation insulating film 146P may be conformally deposited.

The compensation insulating film 146P may include a nitride-based insulating material. For example, the compensation insulating film 146P may include at least one of, for example, silicon nitride (Si₃N₄), silicon oxynitride (SiON), silicon carbonitride (SiCN), silicon oxycarbonitride (SiOCN), or combinations thereof. However, the present disclosure is not limited thereto. A material included in the compensation insulating film 146P may be the same as a material included in the first gate capping film 145.

Referring to FIG. 22, an ion implantation process (IIP) may be performed. Ions may be doped into the compensation insulating film 146P by performing an ion implantation process (IIP). The ions are not uniformly doped into the compensation insulating film 146P.

The ions may be implanted in the third direction Z. Therefore, an amount of ions doped in a portion of the compensation insulating film 146P extending in the first direction X or the second direction Y is larger than an amount of ions doped in the compensation insulating film 146P extending in the third direction Z. That is, the amount of ions doped in a portion of the compensation insulating film 146P disposed on the upper surface of the pre-liner film 165P is greater than the amount of ions doped in a portion of the compensation insulating film 146P disposed on a sidewall of the pre-liner film 165P.

Further, an amount of ions doped in a portion of the compensation insulating film 146P disposed on the first gate capping film 145 is greater than an amount of ions doped in a portion of the compensation insulating film 146P disposed on the source/drain pattern 150.

Referring to FIG. 23, the second gate capping film 146 may be formed by removing the compensation insulating film 146P. The compensation insulating film 146P may be removed using a wet etching process. As described above, the compensation insulating film 146P is doped with the ions via the ion implantation process. The compensation insulating film 146P may have an etch selectivity varying based on the amount of the doped ions. For example, as the amount of the doped ions increases, an amount by which the compensation insulating film 146P is etched may decrease. Conversely, as the amount of the doped ions decreases, the amount by which the compensation insulating film 146P is etched may increase.

As described above, the amount of ions doped in the portion of the compensation insulating film 146P disposed on the upper surface of the pre-liner film 165P is greater than the amount of ions doped in the portion of the compensation insulating film 146P disposed on the sidewall of the pre-liner film 165P. Further, the amount of ions doped in the portion of the compensation insulating film 146P disposed on the first gate capping film 145 is greater than the amount of ions doped in the portion of the compensation insulating film 146P disposed on the source/drain pattern 150.

Based on the reason set forth above, the portion of the compensation insulating film 146P disposed on the sidewall of the pre-liner film 165P and the portion of the compensation insulating film 146P disposed on the source/drain pattern 150 may be selectively removed. This is because the portion of the compensation insulating film 146P disposed on the first gate capping film 145 is doped with the highest amount of ions in comparison with other portions of the compensation insulating film 146P, and thus, may have the lowest etching rate. That is, the second gate capping film 146 may be formed only on the first gate capping film 145. Also, in the wet etching process, the pre-liner film 165P may prevent the etch stop film 160 from being damaged by the wet etchant.

Referring to FIG. 24, the liner film 165 may be formed by removing a portion of the pre-liner film 165P. In this regard, the portion of the pre-liner film 165P may be removed to expose a portion of the source/drain pattern 150. Accordingly, a vertical level of a bottom surface of the liner film 165 may be higher than that of the bottom surface of the contact trench 170t. An upper surface of a portion of the source/drain pattern 150 under the contact trench 170t may have a concave curved surface recessed toward the upper surface of the substrate 100.

Referring to FIG. 25, a pre-first source/drain contact 170P may be formed. The pre-first source/drain contact 170P may fill the contact trench 170t. Further, the pre-first source/drain contact 170P may cover the second gate capping film 146.

The contact silicide layer 155 may be formed along a profile of a boundary surface between the source/drain pattern 150 and the pre-first source/drain contact 170P. In an embodiment of the present disclosure, a plasma of a metal may be produced to deposit a metal layer on the source/drain pattern 150 at high temperature, and the metal layer may react with silicon of the source/drain pattern 150 simultaneously as it is being deposited, forming a metal silicide layer as the contact silicide layer 155.

The pre-first source/drain contact 170P may include a pre-source/drain barrier film 170BL_P and a pre-source/drain filling film 170FL_P disposed on the pre-source/drain barrier film 170BL_P. The pre-source/drain barrier film 170BL_P may extend along an inner sidewall and a bottom surface of the contact trench 170t and an upper surface of the second gate capping film 146. To form the pre-source/drain barrier film 170BL_P, a process such as, for example, an atomic layer deposition (ALD) process, a chemical vapor deposition (CVD) process, or a combination thereof may be used. The pre-source/drain filling film 170FL_P may be disposed on the pre-source/drain barrier film 170BL_P.

The pre-source/drain barrier film 170BL_P may include, for example, at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), or a two-dimensional (2D) material. In the semiconductor device according to an embodiment of the present disclosure, the 2D material may be a metallic material and/or a semiconductor material. The two-dimensional material (2D material) may include a two-dimensional allotrope or a two-dimensional compound. For example, the two-dimensional material (2D material) may include at least one of graphene, molybdenum disulfide (MoS₂), molybdenum diselenide (MoSe₂), tungsten diselenide (WSe₂), or tungsten disulfide (WS₂). However, the present disclosure is not limited thereto. For example, the above-mentioned 2D materials are only listed by way of example. The 2D material that may be included in the semiconductor device of the present disclosure is not limited to the above-mentioned materials.

The pre-source/drain filling film 170FL_P may include, for example, at least one of aluminum (Al), tungsten (W), cobalt (Co), ruthenium (Ru), silver (Ag), gold (Au), manganese (Mn), or molybdenum (Mo).

Unlike what is illustrated, the pre-first source/drain contact 170 may be embodied as a single film.

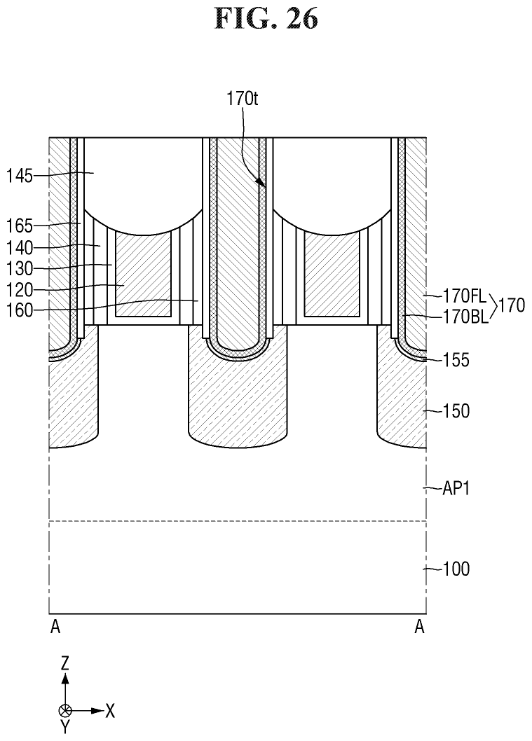

Referring to FIG. 26, the first source/drain contact 170 may be formed. The first source/drain contact 170 may be formed via a planarization process (CMP; Chemical Mechanical Polishing). The second gate capping film 146 may also be removed via a planarization process. For example, the CMP process may be performed to remove the pre-source/drain barrier film 170BL_P, the pre-source/drain filling film 170FL_P, the second gate capping film 146 and the liner film 165 located above the first gate capping film 145 until the upper surface of the first gate capping film 145 is exposed. Further, a portion of the liner film 165 disposed on the first gate capping film 145 may also be removed. In this case, the upper surface of the first gate capping film 145 and the upper surface of the first source/drain contact 170 are coplanar with each other.

Referring to FIG. 27, the first source/drain contact 170 may be formed, but the second gate capping film 146 may not be removed. Using a planarization process, the upper surface of the second gate capping film 146 and the upper surface of the first source/drain contact 170 may be coplanar with each other. For example, the CMP process may be performed to remove the pre-source/drain barrier film 170BL_P and the pre-source/drain filling film 170FL_P located above the second gate capping film 146 until the upper surface of the second gate capping film 146 is exposed. In this regard, the liner film 165 may be disposed between the first gate capping film 145 and the second gate capping film 146.

Although embodiments of the present disclosure have been described with reference to the accompanying drawings, the present disclosure is not limited to the above embodiments, but may be implemented in various different forms. A person skilled in the art may appreciate that the present disclosure may be practiced in other specific forms without departing from the spirit and scope of the present disclosure as defined by the appended claims. Therefore, it should be appreciated that the embodiments of the present disclosure as described above is not restrictive but illustrative in all respects.

What is claimed is:

1. A semiconductor device comprising:
a substrate;
an active pattern disposed on the substrate and extending in a first direction;
a plurality of gate electrodes covering the active pattern and extending in a second direction, the second direction intersecting the first direction;
a gate spacer disposed on a sidewall of each of the plurality of gate electrodes;
a source/drain pattern disposed between adjacent ones of the plurality of gate electrodes;
an etch stop film disposed along a sidewall of the gate spacer and a profile of the source/drain pattern;
an interlayer insulating film disposed between the adjacent ones of the plurality of gate electrodes, wherein a contact trench exposing the source/drain pattern is defined in the interlayer insulating film;
a liner film disposed on an outer sidewall of the contact trench; and
a source/drain contact disposed on the liner film and filling the contact trench, wherein the source/drain contact is connected to the source/drain pattern,
wherein at least a portion of the liner film is disposed in the source/drain pattern.

2. The semiconductor device of claim 1, further comprising a gate capping film disposed on the each of the plurality of gate electrodes,
wherein at least a portion of the liner film is in contact with the gate capping film.

3. The semiconductor device of claim 2, wherein the etch stop film is not disposed on a sidewall of the gate capping film.

4. The semiconductor device of claim 1, wherein the liner film includes a first portion extending in the first direction, and a second portion disposed on the first portion and extending in a third direction, with the third direction intersecting the first direction and the second direction.

5. The semiconductor device of claim 1, wherein a vertical level of a bottom surface of the source/drain contact based on an upper surface of the substrate is lower than a vertical level of a bottom surface of the liner film based on the upper surface of the substrate.

6. The semiconductor device of claim 1, wherein the active pattern includes a lower pattern, and at least one sheet pattern disposed on the lower pattern,
wherein the at least one sheet pattern is in contact with the source/drain pattern.

7. The semiconductor device of claim 1, further comprising a gate contact connected to the each of the plurality of gate electrodes,
wherein an upper surface of the gate contact is coplanar with an upper surface of the source/drain contact.

8. The semiconductor device of claim 1, wherein a thickness of the liner film is constant.

9. The semiconductor device of claim 1, wherein the etch stop film includes a nitride-based insulating material.

10. The semiconductor device of claim 1, wherein the liner film includes an oxide-based insulating material.

11. A semiconductor device comprising:
a substrate;
an active pattern disposed on the substrate and extending in a first direction;
a plurality of gate electrodes covering the active pattern and extending in a second direction, the second direction intersecting the first direction;
a plurality of gate spacers, each being disposed on a sidewall of each of the plurality of gate electrodes;
a first gate capping film disposed on the each of the plurality of gate electrodes and the each of the plurality of gate spacers;
a source/drain pattern disposed between adjacent ones of the plurality of gate electrodes;
an etch stop film disposed along a sidewall of the each of the plurality of gate spacers and a profile of the source/drain pattern;
a liner film extending along a profile of the etch stop film, a sidewall of the first gate capping film, and an upper surface of the first gate capping film, wherein at least a portion of the liner film is disposed in the source/drain pattern;
a second gate capping film disposed on the liner film and overlapping the first gate capping film in a third direction, the third direction intersecting the first direction and the second direction; and
a source/drain contact disposed between the adjacent ones of the plurality of gate electrodes and connected to the source/drain pattern,
wherein the liner film includes an oxide-based insulating material.

12. The semiconductor device of claim 11, wherein an upper surface of the second gate capping film is coplanar with an upper surface of the source/drain contact.

13. The semiconductor device of claim 11, wherein a thickness of the liner film is constant.

14. The semiconductor device of claim 11, wherein the liner film is not disposed on a sidewall of the second gate capping film.

15. The semiconductor device of claim 11, further comprising a gate contact extending through the second gate capping film, the liner film, and the first gate capping film, and being connected to the each of the plurality of gate electrodes,
wherein an upper surface of the gate contact is coplanar with an upper surface of the source/drain contact.

16. The semiconductor device of claim 11, wherein the etch stop film includes a nitride-based insulating material.

17. The semiconductor device of claim 11, wherein the active pattern includes a lower pattern, and at least one sheet pattern disposed on the lower pattern,
wherein the at least one sheet pattern is in contact with the source/drain pattern.

18. A semiconductor device comprising:
a substrate;
an active pattern disposed on the substrate, wherein the active pattern includes a lower pattern extending in a first direction, and at least one sheet pattern spaced apart from the lower pattern in a third direction, the third direction intersecting the first direction;
a field insulating film covering a sidewall of the lower pattern;
a plurality of gate electrodes disposed on the lower pattern and covering the at least one sheet pattern, wherein each of the plurality of gate electrodes extends in a second direction, the second direction intersecting the first direction and the third direction;
a plurality of gate spacers, each being disposed on a sidewall of the each of the plurality of gate electrodes;
a plurality of gate capping films respectively disposed on the plurality of gate electrodes;
a source/drain pattern disposed between adjacent ones of the plurality of gate electrodes, and connected to the at least one sheet pattern;
an etch stop film disposed along an upper surface of the field insulating film, a sidewall of the each of the plurality of gate spacers, and a profile of the source/drain pattern;
an interlayer insulating film disposed between the adjacent ones of the plurality of gate electrodes, wherein a contact trench exposing the source/drain pattern is defined in the interlayer insulating film;
a liner film disposed on an outer sidewall of the contact trench; and
a source/drain contact disposed on the liner film, and filling the contact trench, wherein the source/drain contact is connected to the source/drain pattern,
wherein a vertical level of a bottom surface of the source/drain contact based on an upper surface of the substrate is lower than a vertical level of a bottom surface of the liner film based on the upper surface of the substrate,
wherein the etch stop film includes a nitride-based insulating material,
wherein the liner film includes an oxide-based insulating material, and
wherein at least a portion of the liner film is in contact with the source/drain pattern.

19. The semiconductor device of claim 18, wherein the etch stop film is not disposed on a sidewall of each of the plurality of gate capping films.

20. The semiconductor device of claim 18, further comprising a gate contact extending through each of the plurality of gate capping films, and being connected to the each of the plurality of gate electrodes,
wherein an upper surface of the gate contact is coplanar with each of an upper surface of the source/drain contact and an upper surface of the each of the plurality of gate capping films.
